(19) United States
(12) Patent Application Publication
(10) Pub. No.: US 2012/0045876 A1
(43) Pub. Date: Feb. 23, 2012

(54) METHOD FOR MANUFACTURING A SEMICONDUCTOR DEVICE

(75) Inventors: Takaaki KAWAHARA, Kanagawa (JP); Shinsuke Sakashita, Kanagawa (JP); Masaru Kadoshima, Kanagawa (JP); Hiroshi Umeda, Kanagawa (JP)

(73) Assignee: RENESAS ELECTRONICS CORPORATION

(21) Appl. No.: 13/183,996

(22) Filed: Jul. 15, 2011

(30) Foreign Application Priority Data
Aug. 20, 2010 (JP) 2010-184563

(51) Int. Cl. H01L 21/8238

(52) U.S. Cl. 438/231; 257/E21.634

(57) ABSTRACT

There is provided a technology capable of preventing the increase in threshold voltages of n channel type MISFETs and p channel type MISFETs in a semiconductor device including CMISFETs having high dielectric constant gate insulation films and metal gate electrodes. When a rare earth element or aluminum is introduced into a Hf-containing insulation film which is a high dielectric constant gate insulation film for the purpose of adjusting the threshold value of the CMISFET, a threshold adjustment layer including a lanthanum film scarcely containing oxygen, and a threshold adjustment layer including an aluminum film scarcely containing oxygen are formed over the Hf-containing insulation film in an nMIS formation region and a pMIS formation region, respectively. This prevents oxygen from being diffused from the threshold adjustment layers into the Hf-containing insulation film and the main surface of a semiconductor substrate.

### CROSS-REFERENCE TO RELATED APPLICATIONS

The disclosure of Japanese Patent Application No. 2010-184563 filed on Aug. 20, 2010 including the specification, drawings and abstract is incorporated herein by reference in its entirety.

### BACKGROUND

The present invention relates to a method for manufacturing a semiconductor device. More particularly, it relates to a technology effectively applicable to a manufacturing technology of a semiconductor device including CMISFETs having high dielectric constant gate insulation films.

Over a semiconductor substrate, a gate insulation film is formed. Over the gate insulation film, a gate electrode is formed. By ion implantation or the like, source/drain regions are formed. As a result, there can be formed a MISFET (Metal Insulator Semiconductor Field Effect Transistor: MIS field effect transistor, or MIS transistor).

Further, in a CMISFET (Complementary MISFET), there is adopted the following so-called dual gate: in order to achieve low threshold voltages in both of an n channel type MISFET and a p channel type MISFET, gate electrodes are formed using materials having mutually different work functions (for polysilicon, Fermi levels). In other words, n type impurities are introduced into the polysilicon film forming the gate electrode of the n channel type MISFET. Whereas, p type impurities are introduced into the polysilicon film forming the gate electrode of the p channel type MISFET. As a result, the work function (Fermi level) of the material for the gate electrode of the n channel type MISFET becomes in the vicinity of the conduction band of silicon. In addition, the work function (Fermi level) of the material for the gate electrode of the p channel type MISFET becomes in the vicinity of the valence band of silicon. Thus, the threshold voltages are reduced.

However, in recent years, with miniaturization of CMISFET elements, the film thickness reduction of the gate insulation film advances. This has led to unnegligible effects of depletion of the gate electrode when a polysilicon film is used for the gate electrode. For this reason, there is a technology of inhibiting the gate electrode depletion phenomenon using a metal gate electrode as the gate electrode.

Further, with miniaturization of CMISFET elements, the film thickness reduction of the gate insulation film advances. Thus, when a thin silicon oxide film is used as the gate insulation film, the following so-called tunnel current occurs: electrons flowing through the channel of the MISFET tunnel through the barrier formed by the silicon oxide film, and flow into the gate electrode. For this reason, there is the following technology: as the gate insulation film, a material with a higher dielectric constant than that of the silicon oxide film is used; as a result, the physical film thickness is increased even with the same capacitance; this results in reduction of the leakage current.

Patent Literature 1 (US patent No. 2009/0152636A1) indicates the following: as the member for the cap layer formed over the high dielectric constant film (high-k film) which is a gate insulation film, a film including La (lanthanum) is used. However, herein, as the materials for the cap layer, films including oxides of lanthanum or other rare earth elements may be used, not limited to a lanthanum film.

Whereas, Non-Patent Literature 1 describes the technology on a CMISFET using a metal gate electrode and a high dielectric constant gate insulation film.

### Patent Literature 1

US patent No. 2009/0152636A1

### Non-Patent Literature

### Non-Patent Literature 1

T. Kawahara, and twelve other members, “Application of PVD-LaO with Angstrom-Scale Controllability to Metal/Cap/High-k Gate Stacks”, “International Workshop on Dielectric Thin Films for Future ULSI Devices: Science and Technology”, (Japan), 2008, p. 32

### SUMMARY

A study by the present inventors revealed the following.

When a metal gate electrode is used, the problem of depletion of the gate electrode can be solved. However, as compared with the case where a polysilicon gate electrode is used, the absolute values of the threshold voltages are larger at both of the n channel type MISFET and the p channel type MISFET. For this reason, when a metal gate electrode is applied, reduction of the threshold value (reduction of the absolute value of the threshold voltage) is demanded. However, when the n channel type MISFET and the p channel type MISFET use the same materials for the metal gate electrodes and the gate insulation films, a reduction in threshold value of one of the n channel type MISFET and the p channel type MISFET conversely results in an increase in threshold value of the other.

Accordingly, it is desirable to enable independent control of respective threshold voltages of the n channel type MISFET and the p channel type MISFET. Thus, in order to enable independent control of respective threshold voltages of the n channel type MISFET and the p channel type MISFET, it can be considered that different insulating materials are selected for the gate insulation film of the n channel type MISFET and the gate insulation film of the p channel type MISFET.

As a high dielectric constant film (high-k film) for the gate insulation film, a Hf-series gate insulation film which is a Hf-containing high dielectric constant film is excellent. However, when to the Hf-series gate insulation film in the n channel type MISFET, a rare earth element (in particular preferably, lanthanum) is introduced, the n channel type MISFET can be reduced in threshold value. On the other hand, when to the Hf-series gate insulation film in the p channel type MISFET, a rare earth element (particularly, lanthanum) is introduced, the p channel type MISFET is increased in threshold value. For this reason, to the Hf-series gate insulation film in the n channel type MISFET, a rare earth element (particularly, lanthanum) is selectively introduced; whereas, to the Hf-series gate insulation film in the p channel type MISFET, a rare earth element (particularly, lanthanum) is not introduced. As a result, it is possible to reduce the threshold value of the n channel type MISFET without increasing the absolute value of the threshold vale of the p channel type MISFET.

As a method in which to the Hf-series gate insulation film in the n channel type MISFET, a rare earth element (particularly, lanthanum) is selectively introduced, and to the Hf-series gate insulation film in the p channel type MISFET, a rare earth element (particularly, lanthanum) is not introduced, the following process can be considered.

A Hf-series gate insulation film such as a HfSiON film is formed over the entire main surface of a semiconductor substrate including, for example, single-crystal silicon. Over the entire surface of the Hf-series gate insulation film, as a threshold adjustment layer, a lanthanum oxide (e.g., La₂O₃) film is formed. Over the lanthanum oxide film, a photoresist film is formed. Subsequently, by etching using the photoresist film as an etching mask, the lanthanum oxide film in the p channel type MISFET forming region is selectively removed. Then, the photoresist film is removed. Subsequently, the semiconductor substrate is subjected to a heat treatment. As a result, it is possible to introduce lanthanum into the Hf-series gate insulation film in the n channel type MISFET forming region. Then, the lanthanum oxide film not reacted with the Hf-series gate insulation film is removed.

At this step, in the p channel type MISFET forming region, the lanthanum oxide film is not formed. Therefore, lanthanum is not introduced into the Hf-series gate insulation film in the p channel type MISFET forming region. As a result, it is possible to selectively introduce lanthanum into the Hf-series gate insulation film in the n channel type MISFET, and to prevent lanthanum from being introduced into the Hf-series gate insulation film in the p channel type MISFET.

However, a study by the present inventors revealed that this process has the following problem. Namely, in order to introduce, for example, lanthanum, into the high dielectric constant film for a Hf-series gate insulation film, over the Hf-series gate insulation film, a lanthanum oxide film is formed, and is subjected to a heat treatment. As a result, not only lanthanum but also oxygen (O) in the lanthanum oxide film are introduced into the Hf-series gate insulation film. When oxygen is excessively introduced into the Hf-series gate insulation film, oxygen is also introduced through the Hf-series gate insulation film into a portion of the semiconductor substrate underlying the Hf-series gate insulation film. In the oxygen-introduced portion of the main surface of the semiconductor substrate, an insulation film including silicon oxide is formed. Accordingly, between the metal gate electrode over the Hf-series gate insulation film and the semiconductor substrate, there is formed a gate insulation film including the insulation film formed by introduction of oxygen into the main surface of the semiconductor substrate and the Hf-series gate insulation film.

It can also be considered as follows: between the semiconductor substrate and the Hf-series gate insulation film, there is provided a first insulation film including silicon oxide formed before the formation of the Hf-series gate insulation film. Also in this case, oxygen is introduced from the Hf-series gate insulation film into which oxygen has been introduced from the lanthanum oxide film via the first insulation film into the main surface of the semiconductor substrate. Accordingly, at the main surface of the semiconductor substrate, there is formed a second insulation film including silicon oxide. As a result, the insulation film including the first insulation film and the second insulation film, and having a larger film thickness than that of the first insulation film forms the gate insulation film.

When over the Hf-series gate insulation film, the lanthanum oxide film is thus formed, a silicon oxide film is formed at the top surface of the semiconductor substrate. This unfavorably results in an increase in equivalent oxide thickness of the gate insulation film.

Further, as with the n channel type MISFET, as a method for reducing the threshold voltage of the p channel type MISFET, the following method can be considered: after the formation of an aluminum oxide film over the Hf-series gate insulation film of the p channel type MISFET, a heat treatment is preformed, thereby to introduce aluminum into the Hf-series gate insulation film. Incidentally, at this step, it is necessary to prevent aluminum from being introduced into the Hf-series gate insulation film in the n channel type MISFET forming region.

However, as with the threshold adjustment method of the n channel type MISFET using the lanthanum oxide film, aluminum is tried to be introduced into the Hf-series gate insulation film of the p channel type MISFET using an aluminum oxide film. As a result, oxygen in the aluminum oxide film is introduced into the Hf-series gate insulation film and the top surface of the semiconductor substrate. This unfavorably results in an increase in equivalent oxide thickness of the gate insulation film of the p channel type MISFET.

Namely, when the threshold voltage of the n channel type MISFET is reduced, it is important to prevent oxygen from being introduced into the Hf-series gate insulation film from the threshold adjustment layer. Whereas, when the threshold voltage of the p channel type MISFET is reduced, it is important to prevent oxygen from being introduced into the Hf-series gate insulation film from the threshold adjustment layer.

It is an object of the present invention to prevent an increase in equivalent oxide thicknesses of the n channel type MISFET and the p channel type MISFET due to introduction of oxygen into the high dielectric constant gate insulation film.

The foregoing and other objects and novel features of the present invention will be apparent from the description of the present specification and the accompanying drawings.

Summaries of the representative ones of the embodiments disclosed in the present application will be described in brief as follows.

A method for manufacturing a semiconductor device which is one preferred embodiment of the present invention is a method for manufacturing the following semiconductor device. The device has a first MISFET which is a p channel type MISFET in a first region of a semiconductor substrate, and has a second MISFET which is an n channel type MISFET in a second region of the semiconductor substrate. The method includes the steps of: (a) forming a first insulation film for gate insulation films of the first and second MISFETs, and containing Hf in the first region and the second region of the semiconductor substrate; (b) forming an aluminum film over the first insulation film in the first region and over the first insulation film in the second region; (c) forming a cap film over the aluminum film formed in the first region and the second region; (d) removing the cap film and the aluminum film in the second region, and leaving the cap film and the aluminum film in the first region; (e) after the step (d), forming a first metal film including a rare earth element over the first insulation film in the second region and over the cap film in the first region; (f) performing a heat treatment, and causing the first insulation film in the first region to react with the aluminum film, and forming a second insulation film in the first region, and causing the first insulation film in the second region to react with the first metal film, and forming a third insulation film in the second region; (g) after the step (f), removing a portion of the first metal film not reacted in the step (f); (h) after the step (g), removing the cap film in the first region; (i) after the step (h), forming a second metal film over the second insulation film in the first region and over the third insulation film in the second region; (j) patterning the second metal film, and forming a first gate electrode for the first MISFET in the first region, and forming a second gate electrode for the second MISFET in the second region; (k) introducing p type impurities into the main surface of the semiconductor substrate in regions on the opposite sides of the first gate electrode in the first region; (l) introducing n type impurities into the main surface of the semiconductor substrate in regions on the opposite sides of the second gate electrode in the second region; and (m) after the step (k) and the step (l), subjecting the semiconductor substrate to a heat treatment, and forming source/drain regions in the main surface of the semiconductor substrate on respective opposite sides of the first gate electrode and the second gate electrode.

The effects obtainable by the representative ones of the invention disclosed in the present application will be briefly described as follows.

In accordance with one preferred embodiment of the present invention, it is possible to prevent the increase in threshold voltages of the n channel type MISFET and the p channel type MISFET.

### BRIEF DESCRIPTION OF THE DRAWINGS

FIG. 1 is a cross-sectional view showing a method for manufacturing a semiconductor device which is a first embodiment of the present invention;

FIG. 2 is a cross-sectional view showing a method for manufacturing the semiconductor device following FIG. 1;

FIG. 3 is a cross-sectional view showing a method for manufacturing the semiconductor device following FIG. 2;

FIG. 4 is a cross-sectional view showing a method for manufacturing the semiconductor device following FIG. 3;

FIG. 5 is a plan view of a manufacturing apparatus for use in the manufacturing process of the semiconductor device which is the first embodiment of the present invention;

FIG. 6 is a cross-sectional view showing a method for manufacturing the semiconductor device following FIG. 4;

FIG. 7 is a cross-sectional view showing a method for manufacturing the semiconductor device following FIG. 6;

FIG. 8 is a cross-sectional view showing a method for manufacturing the semiconductor device following FIG. 7;

FIG. 9 is a cross-sectional view showing a method for manufacturing the semiconductor device following FIG. 8;

FIG. 10 is a cross-sectional view showing a method for manufacturing the semiconductor device following FIG. 9;

FIG. 11 is a cross-sectional view showing a method for manufacturing the semiconductor device following FIG. 10;

FIG. 12 is a cross-sectional view showing a method for manufacturing the semiconductor device following FIG. 11;

FIG. 13 is a cross-sectional view showing a method for manufacturing the semiconductor device following FIG. 12;

FIG. 14 is a cross-sectional view showing a method for manufacturing the semiconductor device following FIG. 13;

FIG. 15 is a cross-sectional view showing a method for manufacturing the semiconductor device following FIG. 14;

FIG. 16 is a cross-sectional view showing a method for manufacturing the semiconductor device following FIG. 15;

FIG. 17 is a cross-sectional view showing a method for manufacturing the semiconductor device following FIG. 16;

FIG. 18 is a cross-sectional view showing a method for manufacturing the semiconductor device following FIG. 10;

FIG. 19 is a cross-sectional view showing a method for manufacturing the semiconductor device following FIG. 18;

FIG. 20 is a cross-sectional view showing a method for manufacturing a semiconductor device shown as a comparative example;

FIG. 21 is a cross-sectional view showing a method for manufacturing the semiconductor device following FIG. 20;

FIG. 22 is a cross-sectional view showing a method for manufacturing the semiconductor device following FIG. 21;

FIG. 23 is a cross-sectional view showing a method for manufacturing the semiconductor device following FIG. 22;

FIG. 24 is a cross-sectional view showing a method for manufacturing the semiconductor device following FIG. 23;

FIG. 25 is a cross-sectional view showing a method for manufacturing the semiconductor device following FIG. 24;

FIG. 26 is a cross-sectional view showing a method for manufacturing the semiconductor device following FIG. 25;

FIG. 27 is a cross-sectional view showing a method for manufacturing the semiconductor device following FIG. 26;

FIG. 28 is a cross-sectional view showing a method for manufacturing the semiconductor device following FIG. 27;

FIG. 29 is a cross-sectional view showing a method for manufacturing the semiconductor device following FIG. 28;

FIG. 30 is a cross-sectional view showing a method for manufacturing a semiconductor device which is a second embodiment of the present invention;

FIG. 31 is a cross-sectional view showing a method for manufacturing the semiconductor device following FIG. 30;

FIG. 32 is a cross-sectional view showing a method for manufacturing the semiconductor device following FIG. 31;

FIG. 33 is a cross-sectional view showing a method for manufacturing the semiconductor device following FIG. 32;

FIG. 34 is a cross-sectional view showing a method for manufacturing the semiconductor device following FIG. 33;

FIG. 35 is a cross-sectional view showing a method for manufacturing the semiconductor device following FIG. 34;

FIG. 36 is a cross-sectional view showing a method for manufacturing the semiconductor device following FIG. 35;

FIG. 37 is a cross-sectional view showing a method for manufacturing the semiconductor device following FIG. 36;

FIG. 38 is a cross-sectional view showing a method for manufacturing the semiconductor device following FIG. 37;

FIG. 39 is a cross-sectional view showing a method for manufacturing a semiconductor device which is a third embodiment of the present invention;

FIG. 40 is a cross-sectional view showing a method for manufacturing the semiconductor device following FIG. 39;

FIG. 41 is a cross-sectional view showing a method for manufacturing the semiconductor device following FIG. 40;

FIG. 42 is a cross-sectional view showing a method for manufacturing the semiconductor device following FIG. 41;

FIG. 43 is a cross-sectional view showing a method for manufacturing the semiconductor device following FIG. 42; and

FIG. 44 is a cross-sectional view showing a method for manufacturing the semiconductor device following FIG. 43.

### DETAILED DESCRIPTION

Below, embodiments of the present invention will be described in details by reference to the accompanying drawings. Incidentally, in all the drawings for describing the embodiments, the members having the same function are given the same reference signs and numerals, and a repeated description thereon is omitted. Further, in the following embodiments, a description on the same or similar parts will not be repeated in principle, unless particularly required.

### First Embodiment

The manufacturing steps of the present embodiment will be described by reference to the accompanying drawings.

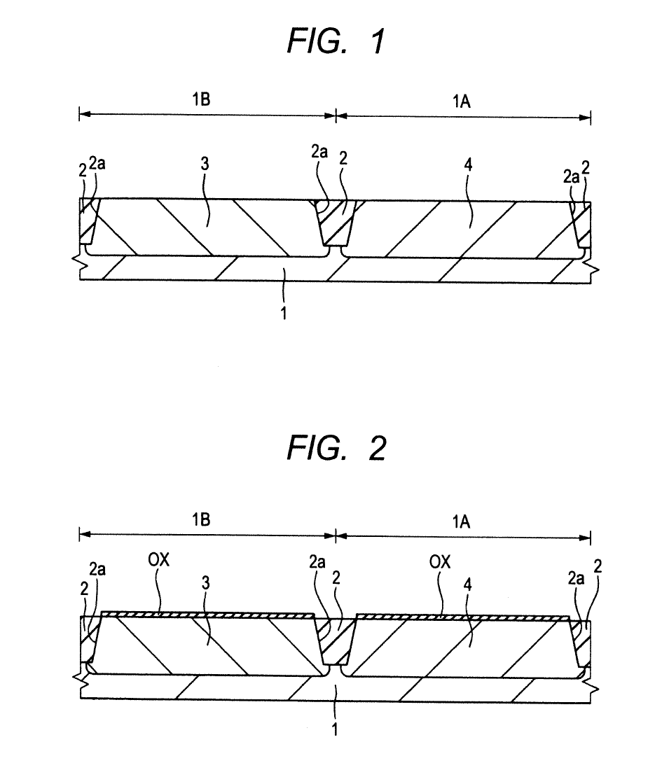

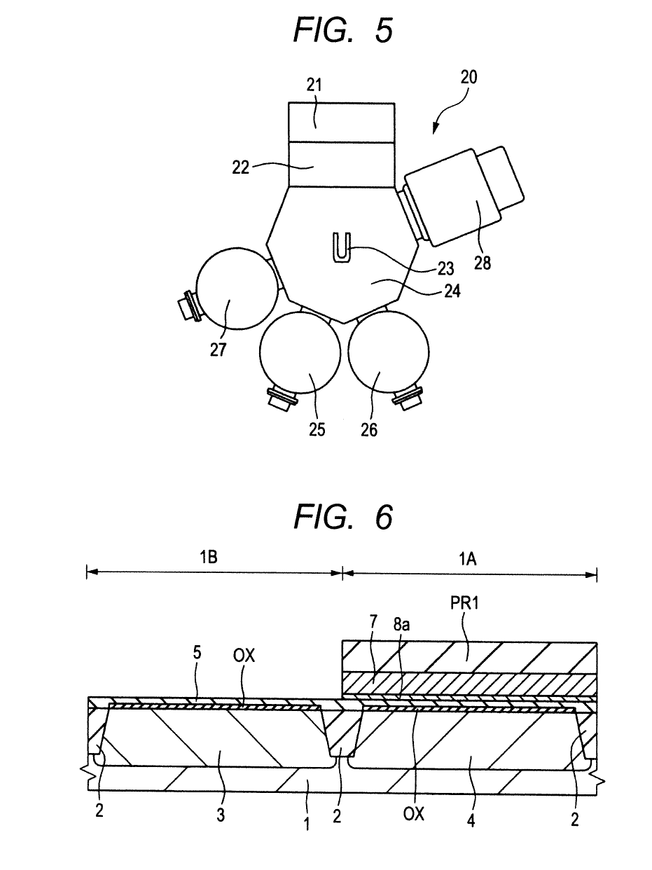

FIGS. 1 to 4 and FIGS. 6 to 19 are each an essential-part cross-sectional view of a semiconductor device which is one embodiment of the present invention, herein, a semiconductor device having CMISFETs (Complementary Metal Insulator Semiconductor Field Effect Transistors) during a manufacturing step. Whereas, FIG. 5 is a plan view of a manufacturing apparatus for use in the manufacturing steps of the semiconductor device which is one embodiment of the present invention.

First, as shown in FIG. 1, there is prepared a semiconductor substrate (semiconductor wafer) 1 including a p type single-crystal silicon having a specific resistance of, for example, about 1 to 10 Ωcm. The semiconductor substrate 1 over which the semiconductor device of the present embodiment is formed has an nMIS formation region 1B which is a region in which an n channel type MISFET (Metal Insulator Semiconductor Field Effect Transistor) is formed, and a pMIS formation region 1A which is a region in which a p channel type MISFET is formed. Then, in the main surface of the semiconductor substrate 1, an element isolation region 2 is formed. The element isolation region 2 includes an insulator such as silicon oxide, and is formed by, for example, a STI (Shallow Trench Isolation) method or a LOCOS (Local Oxidization of Silicon) method. For example, an insulation film embedded in a groove (element isolation groove) 2a formed in the semiconductor substrate 1 can form the element isolation region 2.

Then, in a region of the semiconductor substrate 1 in which the n channel type MISFET is formed (nMIS formation region 1B), a p type well 3 is formed. In a region in which the p channel type MISFET is formed (pMIS formation region 1A), an n type well 4 is formed. At this step, the p type well 3 is formed by ion-implanting p type impurities such as boron (B) or other procedures. The n type well 4 is faulted by ion-implanting n type impurities such as phosphorus (P) or arsenic (As), or other procedures. Further, before the formation of, or after the formation of the p type well 3 and the n type well 4, the upper-layer part of the semiconductor substrate 1 can also be subjected to ion implantation for adjusting the threshold values of MISFETs formed later (so-called channel dope ion implantation), if required.

Then, as shown in FIG. 2, by a thermal oxidation method or CVD (Chemical Vapor Deposition) method using, for example, a lamp type heating chamber, or other methods, a silicon oxide film OX is formed over the surface of the semiconductor substrate 1 by a heat treatment at about 1000° C. FIG. 2 shows the case where the silicon oxide film OX is formed over the surface of the semiconductor substrate 1 by a thermal oxidation method. Although not shown, when the silicon oxide film OX is formed using a CVD method, the silicon oxide film OX is also formed over the element isolation region 2.

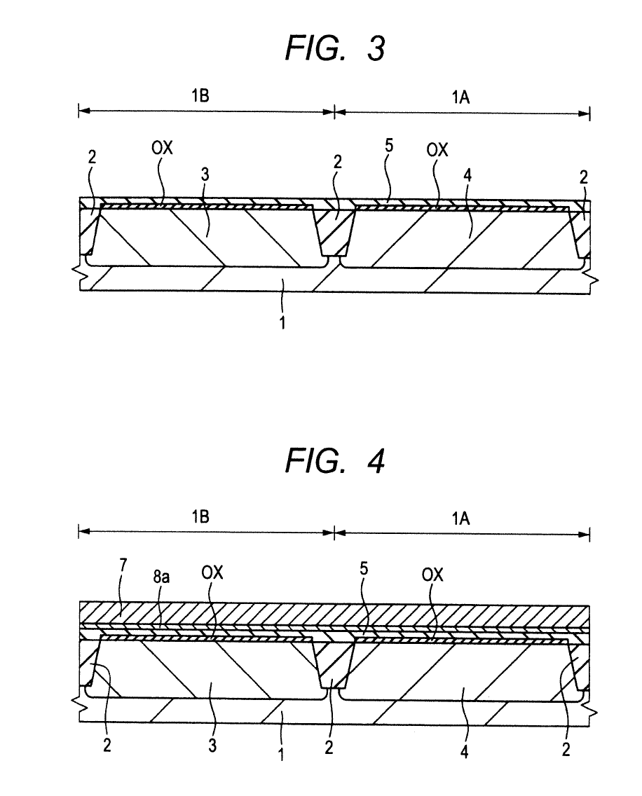

Then, as shown in FIG. 3, over the surface of the semiconductor substrate 1 (i.e., the surface of the silicon oxide film OX), a Hf-containing insulation film 5 for gate insulation film is formed. The Hf-containing insulation film 5 is formed over the entire main surface of the semiconductor substrate 1, and hence, is faulted in both of the nMIS formation region 1B and the pMIS formation region 1A.

The Hf-containing insulation film 5 is an insulation film containing Hf, and includes an insulating material containing Hf (hafnium), and can be preferably a HfSiON film (hafnium silicon oxynitride film), a HfON film (hafnium oxynitride film), or a HfO film (a hafnium oxide film or a hafnium oxide film, and typically, a HfO₂ film). Therefore, the Hf-containing insulation film 5 preferably also further contains oxygen (O) in addition to hafnium (Hf). Incidentally, the HfSiON film is an insulating material film including hafnium (Hf), silicon (Si), oxygen (O), and nitrogen (N). The HfON film is an insulating material film including hafnium (Hf), oxygen (O), and nitrogen (N). The HfO film is an insulating material film including hafnium (Hf) and oxygen (O).

When the Hf-containing insulation film 5 is a HfSiON film, first, a HfSiO film is deposited using an ALD (Atomic Layer Deposition) method or a CVD method. Then, the HfSiO film is subjected to nitriding by a nitriding treatment such as a plasma nitriding treatment (i.e., the HfSiO film is subjected to nitriding, thereby to be a HfSiON film). As a result, a HfSiON film can be formed.

When the Hf-containing insulation film 5 is a HfON film, first, a HfO film (typically, a HfO₂ film) is deposited using an ALD method or a CVD method. Then, the HfO film is subjected to nitriding by a nitriding treatment such as a plasma nitriding treatment (i.e., the HfO film is turned into a HfON film). As a result, a HfON film can be formed.

When the Hf-containing insulation film 5 is a HfO film (typically, a HfO₂ film), it is essential only that a HfO film (typically, a HfO₂ film) is deposited using an ALD method or a CVD method. A nitriding treatment is not required to be performed.

Further, over the surface (silicon side) of the semiconductor substrate 1 (the p type well 3 and the n type well 4), the Hf-containing insulation film 5 can be directly formed. However, herein, before the formation of the Hf-containing insulation film 5, over the surface (silicon side) of the semiconductor substrate 1 (the p type well 3 and the n type well 4), a thin silicon oxide film OX (see FIG. 2) is formed as an interface layer. Over the silicon oxide film OX, the Hf-containing insulation film 5 is formed. The reason why the silicon oxide film OX is formed is as follows: the interface between the gate insulation film and the semiconductor substrate is formed in a SiO₂/Si structure; this reduces the number of defects such as traps in the gate insulation film to as much as that in related-art SiO₂ gate insulation films (gate insulation films including silicon oxide); as a result, the driving capability and the reliability are improved.

Namely, the Hf-containing insulation film tends to have voids formed in the film. Therefore, when only the Hf-containing insulation film is formed as an insulation film between the semiconductor substrate and the gate electrode, a leakage current unfavorably tends to occur between the gate electrode and the semiconductor substrate via a part of the gate electrode formed in the void of the Hf-containing insulation film, or the like. In contrast, a silicon oxide film is formed between the Hf-containing insulation film and the semiconductor substrate. This can prevent the occurrence of a leakage current between the gate electrode and the semiconductor substrate. As a result, the reliability of the semiconductor device can be improved. Incidentally, from the viewpoint of preventing the occurrence of the leakage current, the silicon oxide film OX shown in FIG. 2 is preferably formed with a high density by thermal oxidation at about 1000° C., thereby to prevent the occurrence of voids therein.

Then, as shown in FIG. 4, over the main surface of the semiconductor substrate 1, the threshold adjustment layer (first metal element-containing layer) 8a is formed. The threshold adjustment layer 8a is formed over the Hf-containing insulation film 5 in the nMIS formation region 1B and the pMIS formation region 1A.

In order to reduce the absolute value of the threshold value of the p channel type MISFET (corresponding to a p channel type MISFET Qp described later) formed in the pMIS formation region 1A, the threshold adjustment layer 8a contains a metal element (first metal element) to be introduced into the Hf-series gate insulation film of the p channel type MISFET (p channel type MISFET Qp described later), namely, Al (aluminum). However, the threshold adjustment layer 8a preferably scarcely contains oxygen, and contains oxygen in an amount of only 30 atomic % or less at most, and is assumed to be a film mainly including aluminum. Namely, the threshold adjustment layer 8a scarcely contains aluminum oxide (e.g., Al₂O₃). The threshold adjustment layer 8a can be formed by a sputtering method, or the like. The film thickness (deposited film thickness) thereof can be set at about 1 nm.

Then, over the main surface of the semiconductor substrate 1, namely, over the threshold adjustment layer 8a, a metal nitride film 7 is formed as a hard mask. The metal nitride film 7 is formed over the entire main surface of the semiconductor substrate 1, and hence is formed over the threshold adjustment layer 8a in the nMIS formation region 1B and the pMIS formation region 1A. The metal nitride film 7 is a cap film (antioxidant film) having an action of preventing the threshold adjustment layer 8a including an aluminum film from coming in contact with oxygen or the like in the atmosphere, and preventing the threshold adjustment layer 8a from being oxidized. The metal nitride film 7 is preferably a titanium nitride (TiN) film, a hafnium nitride (HfN) film, or a zirconium nitride (ZrN) film. Out of these, particularly preferred is a titanium nitride (TiN) film. The metal nitride film 7 can be formed using a sputtering method or the like.

At this step, the threshold adjustment layer 8a and the metal nitride film 7 are formed using an apparatus shown in FIG. 5. FIG. 5 is a plan view showing a deposition/heat treatment apparatus 20 including respective deposition devices of an aluminum film, a titanium nitride film, and a lanthanum film, and an annealing device for heat-treating a semiconductor wafer (semiconductor substrate), integrated with each other. The deposition/heat treatment apparatus 20 has an automatic transfer device 21 for transferring a semiconductor substrate (semiconductor wafer) into the deposition/heat treatment apparatus 20, a storage chamber 22 for temporarily keeping on standby therein the semiconductor wafer transferred into the deposition/heat treatment apparatus 20 by the automatic transfer device 21, and a transfer chamber 24 integral with the storage chamber 22. The transfer chamber 24 is coupled with an aluminum film deposition device 25, a titanium nitride film deposition device 26, and a lanthanum film deposition device 27 each for disposing the semiconductor wafer in the inside thereof, and forming a film over the main surface of the semiconductor wafer, and an annealing device 28 for disposing the semiconductor wafer in the inside thereof, and heat-treating the semiconductor wafer, respectively. In the transfer chamber 24, there is disposed a robot arm 23 for transferring the semiconductor wafer in the deposition/heat treatment apparatus 20. Incidentally, the robot arm 23 is disposed in the transfer chamber 24. However, in FIG. 5, for ease of understanding of the drawing, the robot arm 23 is shown as seen through a part of the transfer chamber 24.

In the deposition step described by reference to FIG. 4, first, the inside of the deposition/heat treatment apparatus 20 except for the automatic transfer device 21 and the storage chamber 22 shown in FIG. 5 is evacuated. Then, the inside of the deposition/heat treatment apparatus 20 is set under an inert gas atmosphere (e.g., N₂ (nitrogen) atmosphere).

Then, the semiconductor substrate (semiconductor wafer) 1 shown in FIG. 3 is transferred into the storage chamber 22 by the automatic transfer device 21 shown in FIG. 5. Then, a closed state is established between the storage chamber 22 and the automatic transfer device 21. Thus, the storage chamber 22 is closed so as to prevent the outside air from flowing thereinto. Subsequently, the inside of the storage chamber 22 is evacuated. Then, the semiconductor wafer in the storage chamber 22 is transferred into the aluminum film deposition device 25 by the robot arm 23.

Then, by the aluminum film deposition device 25, the threshold adjustment layer 8a is formed over the main surface of the semiconductor substrate 1 shown in FIG. 4. Then, by the robot arm 23 shown in FIG. 5, the semiconductor wafer in the aluminum film deposition device 25 is transferred into the titanium nitride film deposition device 26.

Then, by the titanium nitride film deposition device 26, over the main surface of the semiconductor substrate 1 shown in FIG. 4, the metal nitride film 7 is formed. Then, by the robot arm 23 shown in FIG. 5, the semiconductor wafer in the titanium nitride film deposition device 26 is transferred into the storage chamber 22. Then, the partition between the storage chamber 22 and the transfer chamber 24 is closed. Then, the atmosphere in the storage chamber 22 is set to be the same atmosphere as the atmosphere. Using the automatic transfer device 21, the semiconductor wafer in the storage chamber 22 is extracted from the inside of the deposition/heat treatment apparatus 20. As a result, the deposition step of the threshold adjustment layer 8a and the metal nitride film 7 described by reference to FIG. 4 is completed.

In this step, the semiconductor wafer over which the threshold adjustment layer 8a is formed is extracted from the inside of the aluminum film deposition device 25. Then, the semiconductor wafer passes through the transfer chamber 24 with a nitrogen atmosphere, and is transferred into the titanium nitride film deposition device 26. Therefore, without being exposed to the atmosphere outside the deposition/heat treatment apparatus 20, the threshold adjustment layer 8a and the metal nitride film 7 can be continuously formed. When the aluminum film deposition device 25 and the titanium nitride film deposition device 26 are not integrated via the transfer chamber 24, and are independent individual devices, in the process of transfer from the inside of the aluminum film deposition device 25 into the titanium nitride film deposition device 26, the semiconductor wafer is exposed to the atmosphere. Thus, the threshold adjustment layer 8a before the formation of the metal nitride film 7 reacts with oxygen or moisture in the atmosphere to be oxidized. However, herein, there is used the deposition/heat treatment apparatus 20 including the aluminum film deposition device 25 and the titanium nitride film deposition device 26. For this reason, the threshold adjustment layer 8a before the formation of the metal nitride film 7 is not exposed to the atmosphere. This can prevent the introduction of oxygen from the atmosphere into the threshold adjustment layer 8a.

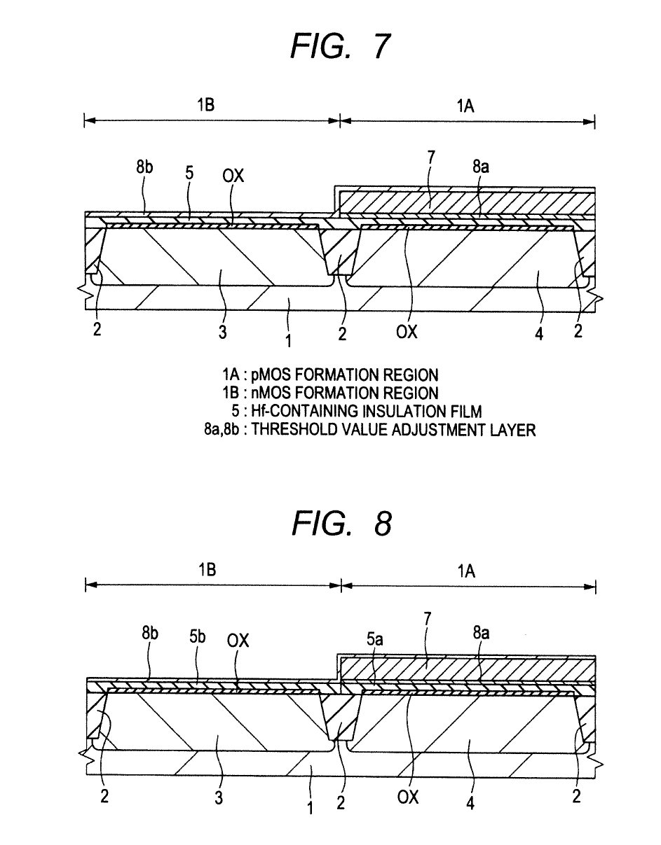

Incidentally, herein, the lanthanum film deposition device 27 and the annealing device 28 are not used. Therefore, the deposition/heat treatment apparatus 20 is not required to have the lanthanum film deposition device 27 and the annealing device 28. In that case, in the formation step of the threshold adjustment layer 8b, and the heat treatment step of the semiconductor substrate 1 described later by reference to FIGS. 7 and 8, there is used the deposition/heat treatment apparatus 20 having the lanthanum film deposition device 27 and the annealing device 28 as shown in FIG. 5.

Further, the deposition/heat treatment apparatus 20 has the aluminum film deposition device 25, the titanium nitride film deposition device 26, and the lanthanum film deposition device 27. However, in place of the devices, devices for depositing films including different materials according to the film type to be deposited may be appropriately disposed. For example, when the threshold adjustment layer 8b described later is formed of yttrium (Y), the lanthanum film deposition device 27 shown in FIG. 5 may be the yttrium film deposition device.

Then, as shown in FIG. 6, over the main surface of the semiconductor substrate 1, namely, over the metal nitride film 7, a photoresist film is applied. The photoresist film is subjected to exposure and development, thereby to form a photoresist pattern (resist pattern) PR1 as a resist pattern.

The photoresist pattern PR1 is formed over a portion of the metal nitride film 7 in the pMIS formation region 1A, but is not formed in the nMIS formation region 1B. For this reason, the portion of the metal nitride film 7 in the pMIS formation region 1A is covered with the photoresist pattern PR1. However, the portion of the metal nitride film 7 in the nMIS formation region 1B is not covered with the photoresist pattern PR1, and is in an exposed state.

Then, using the photoresist pattern PR1 as an etching mask, the metal nitride film 7 and the threshold adjustment layer 8a are wet etched. By the wet etching step, portions of the metal nitride film 7 and the threshold adjustment layer 8a in the nMIS formation region 1B are etched and removed. However, portions of the metal nitride film 7 and the threshold adjustment layer 8a in the pMIS formation region 1A are covered with the photoresist pattern PR1, and hence are left without being etched. As a result, a portion of the Hf-containing insulation film 5 in the nMIS formation region 1B is exposed. However, portions of the Hf-containing insulation film 5 and the threshold adjustment layer 8a in the pMIS formation region 1A are kept to be covered with the metal nitride film 7 (i.e., to be not exposed).

Then, as shown in FIG. 7, after removing the photoresist pattern PR1, over the main surface of the semiconductor substrate 1, the threshold adjustment layer (first metal element-containing layer) 8b is formed. In the wet etching step described by reference to FIG. 6, the portion of the metal nitride film 7 in the nMIS formation region 1B was removed, and the portion of the metal nitride film 7 in the pMIS formation region 1A was left. Therefore, herein, the threshold adjustment layer 8b is formed over the Hf-containing insulation film 5 in the nMIS formation region 1B, and is formed over the metal nitride film 7 in the pMIS formation region 1A. For this reason, in the nMIS formation region 1B, the threshold adjustment layer 8b and the Hf-containing insulation film 5 are in contact with each other. However in the pMIS formation region 1A, the threshold adjustment layer 8b and the Hf-containing insulation film 5 are not in contact with each other because the threshold adjustment layer 8a and the metal nitride film 7 are interposed therebetween.

In order to reduce the absolute value of the threshold value of the n channel type MISFET (corresponding to an n channel type MISFET Qn described later) formed in the nMIS formation region 1B, the threshold adjustment layer 8b contains a metal element (first metal element) to be introduced into the Hf-series gate insulation film of the n channel type MISFET (n channel type MISFET Qn described later), namely, a rare earth element (in particular preferably, La).

Therefore, the threshold adjustment layer 8b contains a rare earth element, and in particular preferably, contains La (lanthanum). The threshold adjustment layer 8b can be formed by a sputtering method or the like. The film thickness (deposited film thickness) can be set at about 1 nm. However, the threshold adjustment layer 8b preferably scarcely contains oxygen, and contains oxygen in an amount of only 30 atomic % or less at most, and is assumed to be a film mainly including lanthanum (La). Namely, the threshold adjustment layer 8b scarcely contains lanthanum oxide (e.g., La₂O₃).

Incidentally, in the present application, rare earths or rare earth elements denote lanthanoids of from lanthanum (La) to lutetium (Lu), and in addition, scandium (Sc) and yttrium (Y). However, for example, lanthanum is higher in dielectric constant than yttrium, and is suitable as a material for a high dielectric constant film (high-k film). For this reason, in the present embodiment, the element forming the threshold adjustment layer 8b is preferably lanthanum.

Below, the rare earth element contained in the threshold adjustment layer 8b will be expressed as Ln. Whereas, the Hf-containing gate insulation film will be referred to as a Hf-series gate insulation film. Further, as described above, the threshold adjustment layer 8b scarcely contains oxygen. The same is also true even when the material for the threshold adjustment layer 8b is a rare earth element other than La. The material forming the threshold adjustment layer 8b is assumed to scarcely contain an oxide.

Further, in the formation step of the threshold adjustment layer 8b, there is used the deposition/heat treatment apparatus 20 having the lanthanum film deposition device 27 and the annealing device 28 as shown in FIG. 5. Herein, as described in the disposition step of FIG. 4, the semiconductor substrate 1 (semiconductor wafer) shown in FIG. 6 is transferred into the storage chamber 22 shown in FIG. 5. Then, by the robot arm 23, the semiconductor wafer in the storage chamber 22 is transferred into the lanthanum film deposition device 27. Thus, by the lanthanum film deposition device 27, the threshold adjustment layer 8b shown in FIG. 7 is formed. At this step, the inside of the deposition/heat treatment apparatus 20 is under an inert gas atmosphere (e.g., N₂ (nitrogen) atmosphere).

Then, as shown in FIG. 8, the semiconductor substrate 1 is subjected to a heat treatment. The heat treatment step can be performed at a heat treatment temperature within the range of 780 to 850° C. in an inert gas atmosphere (e.g., N₂ (nitrogen) atmosphere). By the heat treatment, in the nMIS formation region 1B, the Hf-containing insulation film 5 and the threshold adjustment layer 8b are allowed to react with each other. In the pMIS formation region 1A, the Hf-containing insulation film 5 and the threshold adjustment layer 8a are allowed to react with each other. Namely, by the heat treatment, aluminum forming the threshold adjustment layer 8a and the rare earth element Ln (in particular preferably, La) forming the threshold adjustment layer 8b are introduced (diffused) into portions of the Hf-containing insulation film 5 in the pMIS formation region 1A and the nMIS formation region 1B, respectively.

In the heat treatment step, in the nMIS formation region 1B, the threshold adjustment layer 8b and the Hf-containing insulation film 5 are in contact with each other, and hence both are allowed to react with each other. As a result, the rare earth element Ln (in particular preferably, Ln=La) of the threshold adjustment layer 8b is introduced (diffused) into the Hf-containing insulation film 5. On the other hand, in the pMIS formation region 1A, the threshold adjustment layer 8a and the Hf-containing insulation film 5 are in contact with each other, and hence both are allowed to react with each other. As a result, Al of the threshold adjustment layer 8a is introduced (diffused) into the Hf-containing insulation film 5.

By the heat treatment, as shown in FIG. 8, in the nMIS formation region 1B, the threshold adjustment layer 8b and the Hf-containing insulation film 5 are allowed to react (are blended or mixed) to form a “Hf- and Ln-containing insulation film 5b”. Namely, in the nMIS formation region 1B, the rare earth element (in particular preferably, La) in the threshold adjustment layer 8b is introduced into the Hf-containing insulation film 5. As a result, the Hf-containing insulation film 5 is turned into the Hf- and Ln-containing insulation film 5b. Herein, the rare earth element contained in the threshold adjustment layer 8b is expressed as Ln. For example, when the threshold adjustment layer 8b is a lanthanum layer, Ln=La, and when the threshold adjustment layer 8b is a yttrium layer, Ln═Y.

The Hf- and Ln-containing insulation film 5b includes an insulating material containing Hf (hafnium) and a rare earth element Ln (in particular preferably, Ln=La). The rare earth element Ln contained in the Hf- and Ln-containing insulation film 5b is the same as the rare earth element Ln contained in the threshold adjustment layer 8b. Therefore, when the Hf-containing insulation film 5 is a HfSiON film, the Hf- and Ln-containing insulation film 5b is a HfLnSiON film (a HfLaSiON film when Ln=La). When the Hf-containing insulation film 5 is a HfON film, the Hf- and Ln-containing insulation film 5b is a HfLnON film (a HfLaON film when Ln=La). When the Hf-containing insulation film 5 is a HfO film (typically, a HfO₂ film) the Hf- and Ln-containing insulation film 5b is a HfLnO film (a HfLaO film when Ln=La).

Incidentally, the HfLnSiON film is an insulating material film including hafnium (Hf), a rare earth element Ln (in particular preferably, Ln=La), silicon (Si), oxygen (O), and nitrogen (N). The HfLnON film is an insulating material film including hafnium (Hf), a rare earth element Ln (in particular preferably, Ln=La), oxygen (O), and nitrogen (N). The HfLnO film is an insulating material film including hafnium (Hf), a rare earth element Ln (in particular preferably, Ln=La), and oxygen (O).

However, the threshold adjustment layer 8b is not a rare earth oxide layer as described above, but is a layer mainly including a rare earth element. For this reason, from the threshold adjustment layer 8b, oxygen (O) is scarcely introduced into the Hf-containing insulation film 5.

On the other hand, in the pMIS formation region 1A, as shown in FIG. 8, the threshold adjustment layer 8a and the Hf-containing insulation film 5 are allowed to react (are blended or mixed) to form a “Hf- and Al-containing insulation film 5a”. Namely, in the pMIS formation region 1A, the Al element in the threshold adjustment layer 8a is introduced into the Hf-containing insulation film 5. AS a result, the Hf-containing insulation film 5 is turned into the Hf- and Al-containing insulation film 5a.

The Hf- and Al-containing insulation film 5a includes an insulating material containing Hf (hafnium) and Al (aluminum). Therefore, when the Hf-containing insulation film 5 is a HfSiON film, the Hf- and Al-containing insulation film 5a is a HfAlSiON film. When the Hf-containing insulation film 5 is a HfON film, the Hf- and Al-containing insulation film 5a is a HfAlON film. When the Hf-containing insulation film 5 is a HfO film (typically, a HfO₂ film), the Hf- and Al-containing insulation film 5a is a HfAlO film.

At this step, in the pMIS formation region 1A, from the inside of the threshold adjustment layer 8b over the metal nitride film 7, a rare earth element Ln (in particular preferably, Ln=La) is diffused. As a result, into the top surface of the metal nitride film 7, the rare earth element Ln is introduced. Similarly, in the pMIS formation region 1A, from the inside of the threshold adjustment layer 8a underlying the metal nitride film 7, Al (aluminum) is diffused. As a result, Al (aluminum) is introduced into the bottom surface of the metal nitride film 7.

Incidentally, the HfAlSiON film is an insulating material film including hafnium (Hf), aluminum (Al), silicon (Si), oxygen (O), and nitrogen (N). The HfAlON film is an insulating material film including hafnium (Hf), aluminum (Al), oxygen (O), and nitrogen (N). The HfAlO film is an insulating material film including hafnium (Hf), aluminum (Al), and oxygen (O).

However, the threshold adjustment layer 8a is not a layer mainly including an aluminum oxide layer as described above, but a layer mainly including an Al element. Therefore, from the threshold adjustment layer 8a, oxygen (O) is scarcely introduced into the Hf-containing insulation film 5. Further, the threshold adjustment layers 8a and 8b scarcely contain oxygen. Therefore, into the metal nitride film 7, oxygen is scarcely introduced from the threshold adjustment layers 8a and 8b.

Further, as described by reference to FIG. 2, before the formation of the Hf-containing insulation film 5 (see, FIG. 3), over the surface (silicon side) of the semiconductor substrate 1 (the p type well 3 and the n type well 4), a thin silicon oxide film OX is formed as an interface layer. Over the silicon oxide film OX, the Hf-containing insulation film 5 is formed. In this case, during the heat treatment described by reference to FIG. 8, preferably, the reaction between the Hf-containing insulation film 5 and the underlying silicon oxide film OX is inhibited, so that the silicon oxide film OX as the interface layer is left. Namely, preferably, in the nMIS formation region 1B, as the interface layer between the Hf- and Ln-containing insulation film 5b and the semiconductor substrate 1 (p type well 3), the silicon oxide film OX is left; whereas, in the pMIS formation region 1A, as the interface layer between the Hf- and Al-containing insulation film 5a and the semiconductor substrate 1 (n type well 4), the silicon oxide film OX is left. As a result, it is possible to form a favorable device which is inhibited in deterioration of the driving force and the reliability.

Incidentally, in the heat treatment step described by reference to FIG. 8, there is used the annealing device 28 in the deposition/heat treatment apparatus 20 as shown in FIG. 5. Herein, the semiconductor substrate 1 (semiconductor wafer) over which the threshold adjustment layer 8b is formed as shown in FIG. 7 is transferred from the inside of the lanthanum film deposition device 27 shown in FIG. 5 into the annealing device 28 by the robot arm 23. By the annealing device 28, the heat treatment described by reference to FIG. 8 is performed. At this step, the semiconductor wafer passes through the inside of the transfer chamber 24 with an inert gas atmosphere (e.g., N₂(nitrogen) atmosphere), and is transferred from the inside of the lanthanum film deposition device 27 into the annealing device 28. For this reason, during transfer from the inside of the lanthanum film deposition device 27 into the annealing device 28, the semiconductor wafer is not exposed to the atmosphere. Therefore, the threshold adjustment layer 8b formed in FIG. 7 is transferred into the annealing device without being exposed to the atmosphere, to be subjected to a heat treatment, and hence is not oxidized by oxygen, moisture, or the like in the atmosphere.

Incidentally, in the steps described by reference to FIGS. 7 and 8, there are no steps of forming the aluminum film and the metal nitride film. Therefore, the deposition/heat treatment apparatus 20 used in FIGS. 7 and 8 does not have to have the aluminum film deposition device 25 and the titanium nitride film deposition device 26.

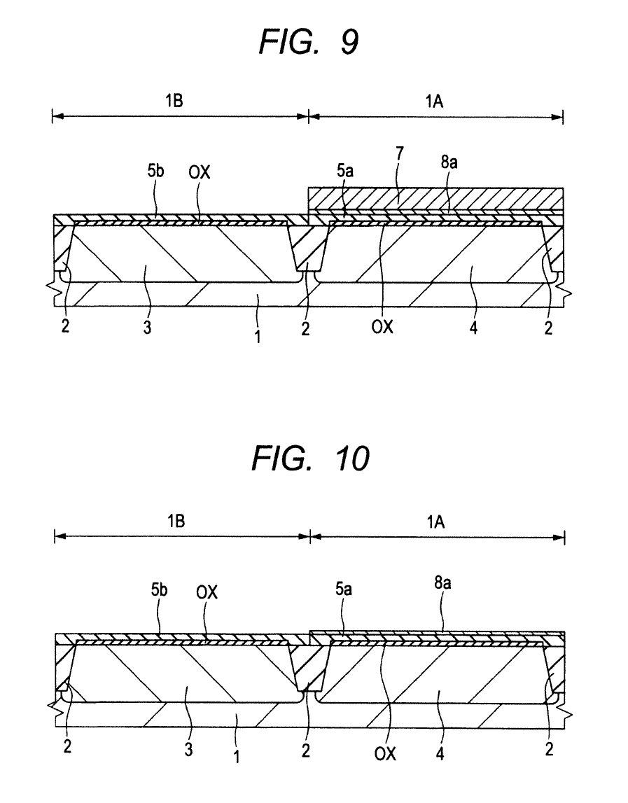

Then, as shown in FIG. 9, the threshold adjustment layer 8b (unreacted threshold adjustment layer 8b) not reacted in the heat treatment step described by reference FIG. 8 is removed by wet etching.

By the wet etching step, in the pMIS formation region 1A, the threshold adjustment layer 8b is removed, so that the metal nitride film 7 is exposed. In the nMIS formation region 1B, there is removed the threshold adjustment layer 8b which has not been completely reacted with the Hf-containing insulation film 5 in the heat treatment described by reference to FIG. 8. As a result, the Hf- and Ln-containing insulation film 5b is exposed. According to the film thickness of the threshold adjustment layer 8b upon formation, during the heat treatment described by reference to FIG. 8, the threshold adjustment layer 8b in the nMIS formation region 1B may react in an amount equivalent to the total thickness thereof with the Hf-containing insulation film 5. However, also in this case, after the wet etching step of the threshold adjustment layer 8b described by reference to FIG. 9, in the pMIS formation region 1A, the metal nitride film 7 is exposed; and in the nMIS formation region 1B, the Hf- and Ln-containing insulation film 5b is exposed.

Then, as shown in FIG. 10, the metal nitride film 7 is removed by wet etching. As a result, the metal nitride film 7 formed in the pMIS formation region 1A is removed, so that the threshold adjustment layer 8a in the pMIS formation region 1A is exposed.

Herein, with the Hf- and Ln-containing insulation film 5b in the nMIS formation region 1B exposed, the wet etching step of the metal nitride film 7 is performed. However, the Hf- and Ln-containing insulation film 5b has a low resistance to a chemical for use in wet etching (e.g., APM solution or hydrofluoric acid), and hence may be damaged by wet etching.

The metal nitride film 7 is more difficult to remove by wet etching when containing oxygen than when not containing oxygen. Therefore, when the metal nitride film 7 contains oxygen in a larger amount, a longer time is taken to remove the metal nitride film 7 by wet etching. When wet etching is thus performed over a long time, the Hf- and Ln-containing insulation film 5b having a low resistance to the chemical for use in wet etching suffers a larger damage.

In contrast, in the present embodiment, the threshold adjustment layer 8a and the threshold adjustment layer 8b shown in FIG. 8 are assumed to be layers scarcely containing oxygen. This prevents the introduction of oxygen from the insides of the threshold adjustment layer 8a and the threshold adjustment layer 8b into the metal nitride film 7. Therefore, oxygen is scarcely introduced into the metal nitride film 7. Accordingly, the metal nitride film 7 can be removed in a short time with ease by wet etching. This can inhibit or prevent the etching damage inflicted on the Hf- and Ln-containing insulation film 5b in the wet etching step. After the wet etching step of the metal nitride film 7, as shown in FIG. 10, both of the Hf- and Ln-containing insulation film 5b in the nMIS formation region 1B, and the threshold adjustment layer 8a in the pMIS formation region 1A are exposed.

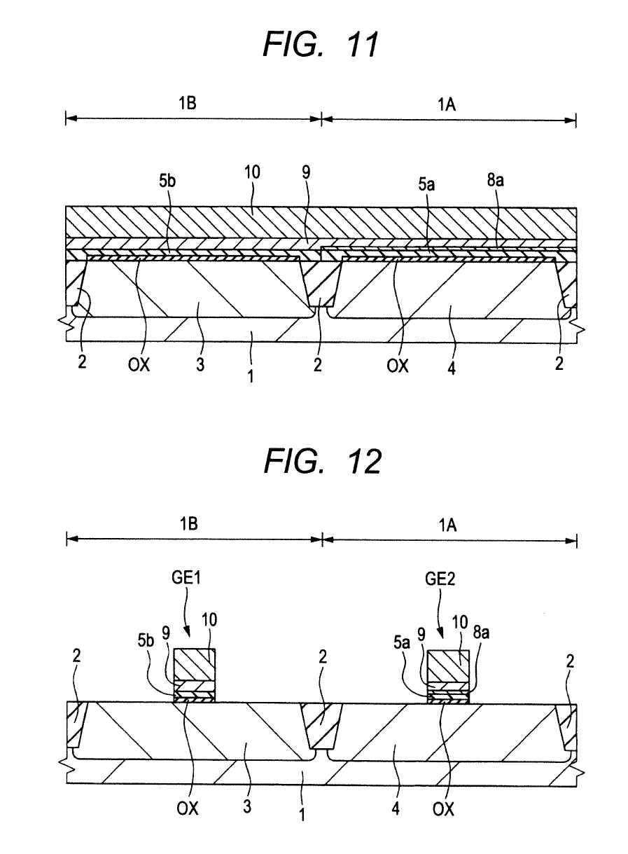

Then, as shown in FIG. 11, over the main surface of the semiconductor substrate 1, a metal film (metal layer) 9 for metal gate (metal gate electrode) is formed. At this step, in the nMIS formation region 1B, over the Hf- and Ln-containing insulation film 5b, the metal film 9 is formed. In the pMIS formation region 1A, over the Hf- and Al-containing insulation film 5a, the metal film 9 is formed via the threshold adjustment layer 8a. The metal film 9 is preferably a titanium nitride (TiN) film, a tantalum nitride (TaN) film, or a tantalum carbide (TaC) film, and most preferably a titanium nitride (TiN) film. The metal film 9 can be formed by, for example, a sputtering method.

Incidentally, in the present application, the metal film (metal layer) denotes a conductive film (conductive layer) showing metal conduction, and includes not only a simple substance metal film or an alloy film, but also a metal compound film (such as a metal nitride film or a metal carbide film) showing metal conduction. For this reason, the metal film 9 is a conductive film showing metal conduction, and preferably, as described above, a titanium nitride (TiN) film, a tantalum nitride (TaN) film, or a tantalum carbide (TaC) film.

Then, over the main surface of the semiconductor substrate 1, namely, over the metal film 9, a silicon film 10 is formed. The silicon film 10 can be a polycrystal silicon film or an amorphous silicon film. However, even when the silicon film 10 is an amorphous film during deposition, it becomes a polycrystal silicon film by the heat treatment after deposition (e.g., activation annealing of impurities introduced for source/drain).

By increasing the thickness of the metal film 9 herein formed, it is also possible that the formation step of the silicon film 10 is omitted (namely, the gate electrode is formed of the metal film 9 without the silicon film 10). However, more preferably, over the metal film 9, the silicon film 10 is formed (namely, the gate electrode is formed of a lamination film of the metal film 9 and the silicon film 10 thereover). The reason for this is as follows: when the thickness of the metal film 9 is too large, the metal film 9 unfavorably may tend to be peeled, or substrate damage due to overetching upon patterning the metal film 9 may unfavorably occur; however, the gate electrode is formed of a lamination film of the metal film 9 and the silicon film 10, so that the thickness of the metal film 9 can be made smaller than when the gate electrode is formed of only the metal film 9; as a result, the problems can be improved. Further, when the silicon film 10 is formed over the metal film 9, the processing methods or processes of related-art polysilicon gate electrodes (gate electrodes including polysilicon) can be followed. For this reason, this case is also advantageous in micro-machinability, manufacturing cost, and yield.

Then, as shown in FIG. 12, the lamination film of the silicon film 10 and the metal film 9 is patterned by a photolithography technology and a dry etching technology. As a result, there are formed gate electrodes GE1 and GE2 each including the metal film 9 and the silicon film 10 over the metal film 9.

The gate electrode GE1 is formed over the Hf- and Ln-containing insulation film 5b in the nMIS formation region 1B. The gate electrode GE2 is formed over the Hf- and Al-containing insulation film 5a in the pMIS formation region 1A. Namely, the gate electrode GE1 including the metal film 9 and the silicon film 10 over the metal film 9 is formed over the surface of the p type well 3 in the nMIS formation region 1B via the Hf- and Ln-containing insulation film 5b as the gate insulation film. The gate electrode GE2 including the metal film 9 and the silicon film 10 over the metal film 9 is formed over the surface of the n type well 4 in the pMIS formation region 1A via the Hf- and Al-containing insulation film 5a as the gate insulation film, and the threshold adjustment layer 8a. The Hf- and Al-containing insulation film 5a and the Hf- and Ln-containing insulation film 5b are both higher in dielectric constant than a silicon oxide film.

Incidentally, upon patterning the silicon film 10 and the metal film 9, the Hf- and Ln-containing insulation film 5b situated under the gate electrode GE1 and the Hf- and Al-containing insulation film 5a situated under the gate electrode GE2 are not removed, and are left. On the other hand, portions of the Hf- and Ln-containing insulation film 5b not covered with the gate electrode GE1, and portions of the Hf- and Al-containing insulation film 5a not covered with the gate electrode GE2 are removed by etching for patterning the silicon film 10 and the metal film 9, or subsequent etching.

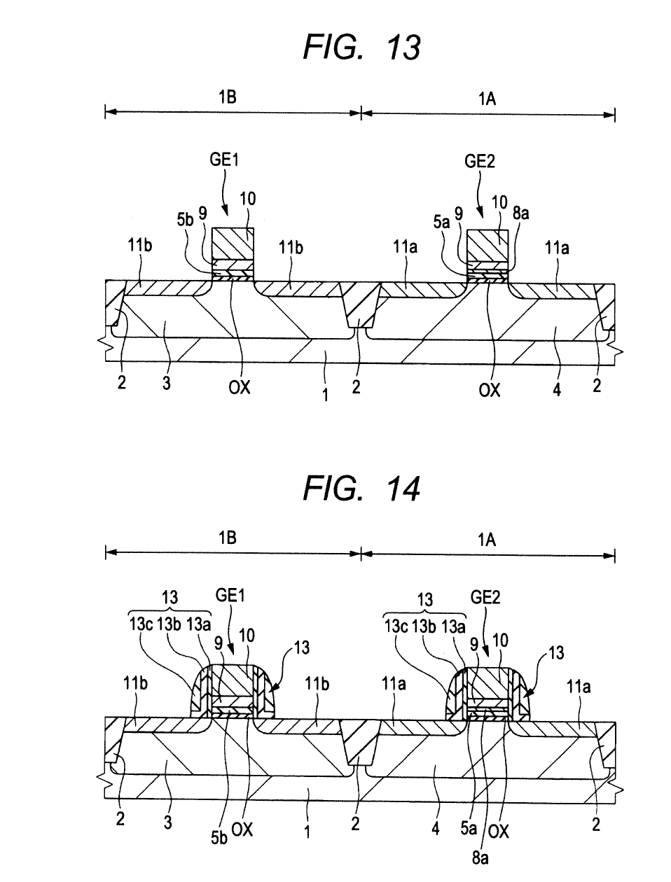

Then, as shown in FIG. 13, into regions of the p type well 3 on the opposite sides of the gate electrode GE1 in the nMIS formation region 1B, n type impurities such as phosphorus (P) or arsenic (As) are ion-implanted. As a result, n⁻ type semiconductor regions (extension regions or LDD (Lightly doped Drain) regions) 11b are formed. During the ion implantation for forming the n⁻ type semiconductor regions 11b, the pMIS formation region 1A is covered with a photoresist film (not shown) as an ion implantation preventive mask. Thus, a portion of the semiconductor substrate 1 (p type well 3) in the nMIS formation region 1B is ion-implanted using the gate electrode GE1 as a mask. Whereas, into regions of the n type well 4 on the opposite sides of the gate electrode GE2 in the pMIS formation region 1A, p type impurities such as boron (B) are ion-implanted. As a result, p⁻ type semiconductor regions (extension regions or LDD regions) 11a are formed. During the ion implantation for forming the p⁻ type semiconductor regions 11a, the nMIS formation region 1B is covered with another photoresist film (not shown) as an ion implantation preventive mask. Thus, a portion of the semiconductor substrate 1 (n type well 4) in the pMIS formation region 1A is ion-implanted using the gate electrode GE2 as a mask. It does not matter whether the n⁻ type semiconductor regions 11b are first formed, or the p⁻ type semiconductor regions 11a are first formed.

Then, as shown in FIG. 14, over the sidewalls of the gate electrodes GE1 and GE2, sidewalls including an insulator (sidewall spacers or sidewall insulation films) 13 are formed. For example, over the semiconductor substrate 1, a silicon nitride film is formed in such a manner as to cover the gate electrodes GE1 and GE2. Then, the silicon nitride film is anisotropically etched (etched back). As a result, over respective sidewalls of the gate electrodes GE1 and GE2, the silicon nitride films 13a are left in a self-alignment manner. Subsequently, over the semiconductor substrate 1, a silicon oxide film 13b and a silicon nitride film 13c are formed sequentially from the bottom in such a manner as to cover the gate electrodes GE1 and GE2. Then, a lamination film of the silicon oxide film 13b and the silicon nitride film 13c is anisotropically etched (etched back). As a result, it is possible to form sidewalls 13 including the silicon nitride films 13a, the silicon oxide films 13b, and the silicon nitride films 13c left over the sidewalls of the gate electrodes GE1 and GE2.

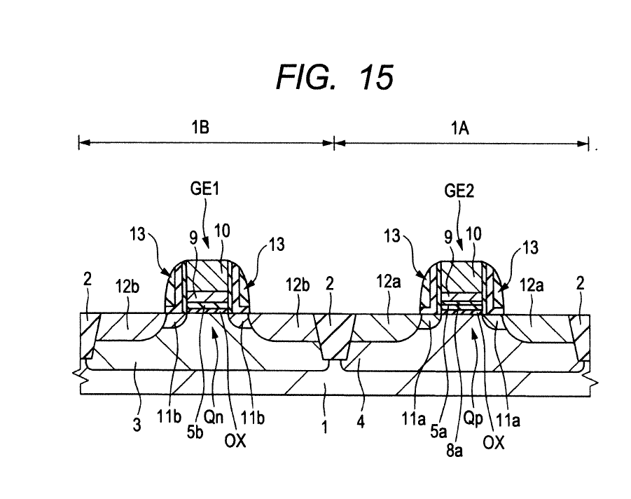

Then, as shown in FIG. 15, into regions of the p type well 3 on the opposite sides of the gate electrode GE1 and the sidewalls 13 in the nMIS formation region 1B, n type impurities such as phosphorus (P) or arsenic (As) are ion-implanted. As a result, n⁺ type semiconductor regions 12b (source and drain) are formed. The n⁺ type semiconductor regions 12b are higher in impurity concentration and larger in junction depth than the n⁻ type semiconductor regions 11b. During the ion implantation for forming the n⁺ type semiconductor regions 12b, the pMIS formation region 1A is covered with a photoresist film (not shown) as an ion implantation preventive mask. Thus, the semiconductor substrate 1 (p type well 3) in the nMIS formation region 1B is ion-implanted using the gate electrode GE1 and the sidewalls 13 over the sidewalls thereof as masks. Accordingly, the n⁻ type semiconductor regions 11b are formed in alignment with the gate electrode GE1. The n⁺ type semiconductor regions 12b are formed in alignment with the sidewalls 13. Further, into regions of the n type well 4 on the opposite sides of the gate electrode GE2 and the sidewalls 13 in the pMIS formation region 1A, p⁺ type impurities such as boron (B) are ion-implanted. As a result, p⁺ type semiconductor regions 12a (source and drain) are formed. The p⁺ type semiconductor regions 12a are higher in impurity concentration and larger in junction depth than the p⁻ type semiconductor regions 11a. During the ion implantation for forming the p⁺ type semiconductor regions 12a, the nMIS formation region 1B is covered with another photoresist (not shown) as an ion implantation preventive mask. Thus, the semiconductor substrate 1 (n type well 4) in the pMIS formation region 1A is ion-implanted using the gate electrode GE2 and the sidewalls 13 over the sidewalls thereof as masks. Accordingly, the p⁻ type semiconductor regions 11a are formed in alignment with the gate electrode GE2. The p⁺ type semiconductor regions 12a are formed in alignment with the sidewalls 13. It does not matter whether the n⁺ type semiconductor regions 12b are formed first, or the p⁺ type semiconductor regions 12a are formed first.

The silicon film 10 forming the gate electrode GE1 in the nMIS formation region 1B is implanted with n type impurities in the ion implantation step for forming the n⁻ type semiconductor regions 11b or the ion implantation step for forming the n⁺ type semiconductor regions 12b, thereby to be an n type silicon film. Whereas, the silicon film 10 forming the gate electrode GE2 in the pMIS formation region 1A is implanted with p type impurities in the ion implantation step for forming the p⁻ type semiconductor regions 11a, or the ion implantation step for forming the p⁺ type semiconductor regions 12a, thereby to be a p type silicon film.

After ion implantation, an annealing treatment (activation annealing or heat treatment) at about 1000° C. is performed for activation of the introduced impurities. As a result, it is possible to activate the impurities introduced into the n⁻ type semiconductor regions 11b, the p⁻ type semiconductor regions 11a, the n⁺ type semiconductor regions 12b, the p⁺ type semiconductor regions 12a, and the like.

Incidentally, when the silicon oxide film OX is not formed over the main surface of the semiconductor substrate 1, by the annealing treatment for activating the source/drain, an insulation film including a silicon oxide film is formed between the semiconductor substrate 1 and the Hf- and Al-containing insulation film 5a and the Hf- and Ln-containing insulation film 5b. The insulation film cannot be formed by adjusting the film thickness with precision as the silicon oxide film OX. Therefore, when the silicon oxide film OX is not formed over the main surface of the semiconductor substrate 1, it becomes difficult to control the increase in equivalent oxide thickness of the gate insulation film including the insulation film. This causes variations in threshold voltages of the MISFETs.

Further, the insulation film is difficult to form in a high density as the silicon oxide film OX. In the insulation film, a larger number of defects occur than in the silicon oxide film. For this reason, when the silicon oxide film OX is not formed, and the insulation film is formed, the effect of preventing the occurrence of a leakage current between the gate electrode and the semiconductor substrate is smaller than when the silicon oxide film OX is formed.

Incidentally, the term “equivalent oxide thickness” herein used denotes the electrically equivalent thickness of the gate insulation film including the Hf- and Al-containing insulation film 5a or the Hf- and Ln-containing insulation film 5b which is a high-k film, or the film thickness of the silicon oxide film showing the same capacitance value as the capacitance shown by the gate insulation film including a high-k film with a given thickness. For example, a high-k film (dielectric constant: 20) with a physical film thickness of 2 nm has an equivalent oxide thickness of 0.4 nm relative to the silicon oxide film. When a silicon oxide film is formed between the gate insulation film including the Hf- and Al-containing insulation film 5a or the Hf- and Ln-containing insulation film 5b and the semiconductor substrate 1, the silicon oxide film is also an insulation film forming the gate insulation film. Therefore, the equivalent oxide thickness is calculated by also including the dielectric constant of the silicon oxide film into the calculation. The silicon oxide film is a film having a lower dielectric constant than those of the high-k films such as the Hf- and Al-containing insulation film 5a and the Hf- and Ln-containing insulation film 5b. For this reason, when a silicon oxide film is formed as a part of the gate insulation film, the value of the equivalent oxide thickness is higher than when the gate insulation film includes only a high-k film.

With an increase in equivalent oxide thickness of the gate insulation film, the threshold voltage of the MISFET having the gate insulation film increases. This hinders the miniaturization, and the reduction of power consumption of the semiconductor device.

Incidentally, the silicon oxide film OX has a role of preventing diffusion of oxygen from the inside of the high-k film into the main surface of the semiconductor substrate. Therefore, when the silicon oxide film OX is not formed, the amount of oxygen diffused from the inside of the high-k film into the main surface of the semiconductor substrate is larger than when the silicon oxide film OX is formed. This results in an increase in film thickness of the insulation film including a silicon oxide film formed between the high-k film and the semiconductor substrate. The silicon oxide film OX is a film which can be controlled in thickness to be formed more thinly than the insulation film. Therefore, when the silicon oxide film OX is not formed, the film thickness of the silicon oxide film forming the gate insulation film becomes larger than when the silicon oxide film OX is formed. For this reason, when the threshold adjustment film contains oxygen, and the silicon oxide film OX is not formed, the equivalent oxide thickness increases.

In contrast, in the present embodiment, in the step described by reference to FIG. 2, over the main surface of the semiconductor substrate 1, the silicon oxide film OX is formed. Therefore, in the annealing treatment for activating the source/drain described by reference to FIG. 15, it is possible to prevent the formation of an insulation film including a silicon oxide film over the top surface of the semiconductor substrate 1. Therefore, in the present embodiment, the formation of the silicon oxide film OX inhibits the formation of the insulation film, which can prevent variations in threshold voltages of the MISFETs. Accordingly, it is possible to enhance the reliability of the semiconductor device.

Further, in the present embodiment, by forming the silicon oxide film OX, it is possible to inhibit the formation of the insulation film. Therefore, it is possible to prevent the following: the insulation film is formed, so that the silicon oxide film forming the gate insulation film increases in thickness; as a result, the threshold voltages of the n channel type MISFET and the p channel type MISFET increase. Thus, it is possible to improve the performances of the semiconductor device.

Further, in the present embodiment, there is provided the silicon oxide film OX having a higher effect of preventing the occurrence of the leakage current between the gate electrodes GE1 and GE2 of the MISFETs and the semiconductor substrate 1 than that of the insulation film. As a result, it is possible to enhance the reliability of the semiconductor device.

Thus, the structure as shown in FIG. 15 is obtained. In the nMIS formation region 1B, as a field-effect transistor, an n channel type MISFET Qn is formed. Whereas, in the pMIS formation region 1A, as a field-effect transistor, a p channel type MISFET Qp is formed.

The gate electrode GE1 functions as the gate electrode of the n channel type MISFET Qn. The Hf- and Ln-containing insulation film 5b and the silicon oxide film OX under the gate electrode GE1 function as the gate insulation film of the n channel type MISFET Qn. Then, the n type semiconductor regions (impurity diffusion layers) functioning as source or drain of the n channel type MISFET Qn are formed of the n⁺ type semiconductor regions 12b and the n⁻ type semiconductor regions 11b. Whereas, the gate electrode GE2 functions as the gate electrode of the p channel type MISFET Qp. The Hf- and Al-containing insulation film 5a and the silicon oxide film OX under the gate electrode GE2 function as the gate insulation film of the p channel type MISFET Qp. Then, the p type semiconductor regions (impurity diffusion layers) functioning as source or drain of the p channel type MISFET Qp are formed of the p⁺ type semiconductor regions 12a and the p⁻ type semiconductor regions 11a. The source/drain regions of the n channel type MISFET Qn and the p channel type MISFET Qp have a LDD structure. Each n⁺ type semiconductor region 12b can be regarded as the semiconductor region for source or drain of the n channel type MISFET Qn. Each p⁺ type semiconductor region 12a can be regarded as the semiconductor region for source or drain of the p channel type MISFET Qp.

Further, the Hf- and Ln-containing insulation film 5b which is the gate insulation film of the n channel type MISFET Qn has a higher content of the rare earth element Ln than that of the Hf- and Al-containing insulation film 5a which is the gate insulation film of the p channel type MISFET Qp. This is due to the following fact: in the heat treatment step described by reference to FIG. 8, into the Hf-containing insulation film (a portion to be the Hf- and Ln-containing insulation film 5b) in the nMIS formation region 1B, the rare earth element Ln was introduced; however, into the Hf-containing insulation film in the pMIS formation region 1A, the rare earth element Ln was not introduced. As a result, the content of the rare earth element Ln in the Hf- and Ln-containing insulation film 5b (i.e., the gate insulation film of the n channel type MISFET Qn) in the nMIS formation region 1B becomes higher than the content of the rare earth element Ln in the Hf- and Al-containing insulation film 5a (i.e., the gate insulation film of the p channel type MISFET Qp) in the pMIS formation region 1A. In other words, it can result that the Hf- and Al-containing insulation film 5a which is the gate insulation film of the p channel type MISFET Qp does not contain a rare earth element.

Similarly, the Hf- and Al-containing insulation film 5a which is the gate insulation film of the p channel type MISFET Qp has a higher content of Al (aluminum) than that of the Hf- and Ln-containing insulation film 5b which is the gate insulation film of the n channel type MISFET Qn. This is due to the following fact: in the heat treatment step described by reference to FIG. 8, into the Hf-containing insulation film in the pMIS formation region 1A, Al (aluminum) was introduced; however, into the Hf-containing insulation film (a portion to be the Hf- and Ln-containing insulation film 5b) in the nMIS formation region 1B, Al (aluminum) was not introduced. As a result, the content of Al (aluminum) in the Hf- and Al-containing insulation film 5a (i.e., the gate insulation film of the p channel type MISFET Qp) in the pMIS formation region 1A becomes higher than the content of Al (aluminum) in the Hf- and Ln-containing insulation film 5b (i.e., the gate insulation film of the n channel type MISFET Qn) in the nMIS formation region 1B. In other words, it can result that the Hf- and Ln-containing insulation film 5b which is the gate insulation film of the n channel type MISFET Qn does not contain Al (aluminum).

Further, in the heat treatment step for activating the source/drain regions described by reference to FIG. 15, from the inside of the threshold adjustment layer 8a between the Hf- and Al-containing insulation film 5a and the metal film 9, aluminum is diffused into the metal film 9. As a result, the metal film 9 becomes a metal film containing TiAlN. When the metal film 9 contains Al, the work function of the p channel type MISFET Qp increases. For the p channel type MISFET Qp, with an increase in work function, the threshold voltage is reduced. Therefore, as described above, aluminum is introduced into the metal film 9. This increases the work function of the p channel type MISFET Qp, which reduces the threshold voltage. As a result, it is possible to enhance the performances of the semiconductor device.

Incidentally, even when the threshold adjustment layer 8a including only aluminum is not left, and the metal film 9 and the Hf- and Al-containing insulation film 5a are in direct contact with each other, aluminum in the metal film 9 and the Hf- and Al-containing insulation film 5a is diffused into the metal film 9. Therefore, similarly, the threshold voltage of the p channel type MISFET Qp can be reduced.

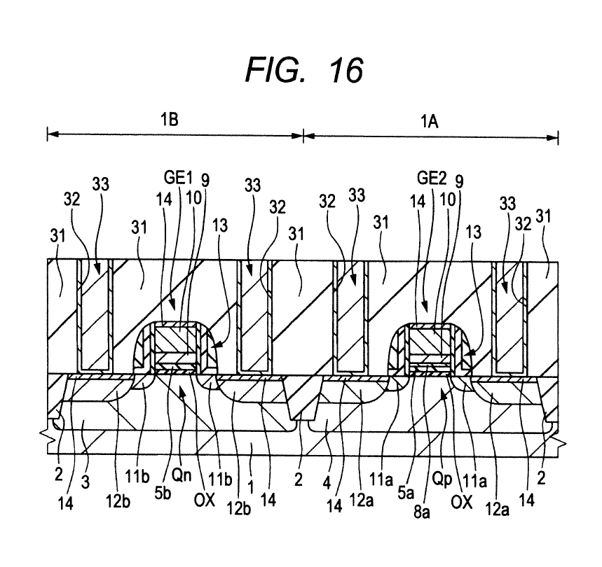

Then, as shown in FIG. 16, by a known salicide technology, over respective top surfaces of the n⁺ type semiconductor regions 12b, the p⁺ type semiconductor regions 12a, and the gate electrodes GE1 and GE2, silicide layers 14 are formed. The material for the silicide layers 14 formed at this step can be NiSi (nickel silicide), CoSi (cobalt silicide), or the like.

Subsequently, over the main surface of the semiconductor substrate 1, an insulation film (interlayer insulation film) 31 is formed in such a manner as to cover the gate electrodes GE1 and GE2. The insulation film 31 includes a simple substance film such as a silicon oxide film, a lamination film of a thin silicon nitride film and a thick silicon oxide film thereover, or the like. After the formation of the insulation film 31, the surface of the insulation film 31 is planarized using, for example, a CMP (Chemical Mechanical Polishing) method.

Then, using a photoresist pattern (not shown) formed over the insulation film 31 as an etching mask, the insulation film 31 is dry etched. As a result, in the insulation film 31, contact holes (through holes or holes) 32 are formed. The contact holes 32 are holes reaching the silicide layers 14 over respective top surfaces of the n⁺ type semiconductor regions 12b, the p⁺ type semiconductor regions 12a, and the gate electrodes GE1 and GE2.

Then, in each contact hole 32, a conductive plug (conductor part for coupling) 33 including tungsten (W) or the like is formed. In order to form the plug 33, for example, over the insulation film 31 including the inside (over the bottom and the sidewall) of the contact hole 32, a barrier conductor film (e.g., a titanium film, a titanium nitride film, or a lamination film thereof) is formed. Then, over the barrier conductor film, a main conductor film including a tungsten film or the like is formed in such a manner as to fill the contact hole 32. The unnecessary portions of the main conductor film and the barrier conductor film over the insulation film 31 are removed by a CMP method, an etching back method, or the like. As a result, the plug 33 can be formed. Incidentally, for simplification of the drawing, in FIG. 16, the barrier conductor film and the main conductor film (tungsten film) forming the plug 33 are shown in an integral form.

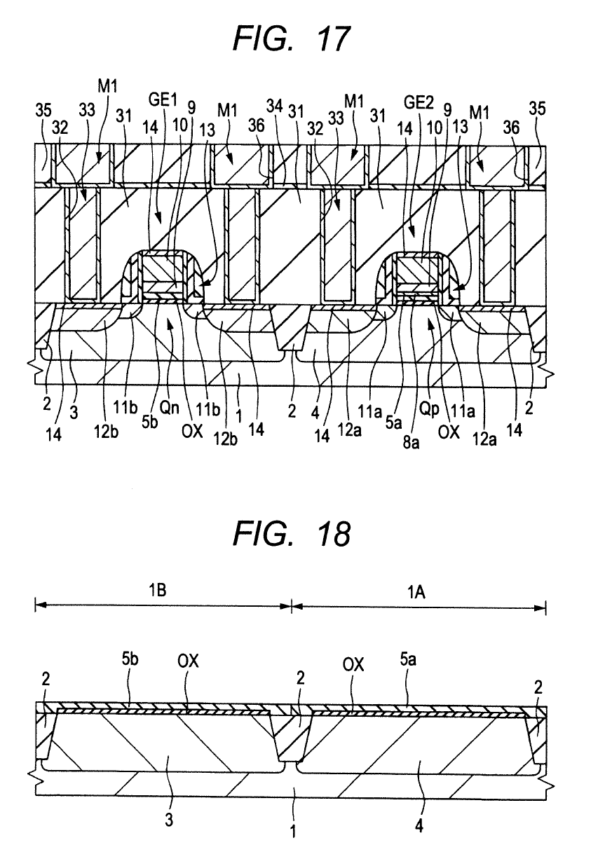

Then, as shown in FIG. 17, over the insulation film 31 including the plugs 33 embedded therein, a stopper insulation film (insulation film for etching stopper) 34 and an insulation film for wire formation (interlayer insulation film) 35 are successively formed. The stopper insulation film 34 is a film serving as an etching stopper for grooving the insulation film 35. Using a material having an etching selectivity with respect to the insulation film 35, for example, the stopper insulation film 34 can be a silicon nitride film, and the insulation film 35 can be a silicon oxide film.

Then, by a single damascene method, a first-layer wire is formed. First, by dry etching using a resist pattern (not shown) as a mask, in prescribed regions of the insulation film 35 and the stopper insulation film 34, wire grooves 36 are formed. Then, over the main surface of the semiconductor substrate 1 (i.e., over the insulation film 35 including over the bottoms and the sidewalls of the wire grooves 36), a barrier conductor film (e.g., a titanium nitride film, a tantalum film, or a tantalum nitride film) is formed. Subsequently, by a CVD method, a sputtering method, or the like, over the barrier conductor film, a seed layer of copper is formed. Further, using an electrolytic plating method or the like, a copper plating film is formed over the seed layer. Thus, the copper plating film fills the inside of each wire groove 36. Then, portions of the copper plating film, the seed layer, and the barrier metal film in regions except for the wire grooves 36 are removed by a CMP method. As a result, the first-layer wires M1 including copper as a main conductive material are formed. Incidentally, for simplification of the drawing, in FIG. 17, the copper plating film, the seed layer, and the barrier conductor film forming the wire M1 are shown in an integral form.

The wires M1 are electrically coupled via the plugs 33 with the n⁺ type semiconductor regions 12b and the p⁺ type semiconductor regions 12a for sources or drains of the n channel type MISFET Qn and the p channel type MISFET Qp, and the like. Then, by a dual damascene method or the like, second- or more-layer wires are formed. As a result, the semiconductor device of the present embodiment is completed. However, herein, the steps are not shown, and a description thereon is omitted. Further, the wire M1 is not limited to a damascene wire, and can also be formed by patterning a conductor film for wire. The wire M1 can be, for example, a tungsten wire or an aluminum wire.

In the manufacturing steps of the semiconductor device, a description was given to the case where, as described in FIG. 17, in the gate structure of the p channel type MISFET Qp, the threshold adjustment layer 8a including Al (aluminum) was not removed, and was left over the Hf- and Al-containing insulation film 5a.

In contrast, the following method can also be considered: in the gate structure of the p channel type MISFET Qp, the threshold adjustment layer 8a which is an aluminum film is not left between the metal nitride film 7 and the Hf- and Al-containing insulation film 5a; thus, the semiconductor device of the present embodiment is formed. In this case, the following can be considered: for the threshold adjustment layer 8a, by the heat treatment step described by reference to FIG. 8, Al atoms are introduced in an amount equivalent to the total film thickness into the Hf-containing insulation film 5 (see FIG. 7) in the pMIS formation region 1A, resulting in the formation of the Hf- and Al-containing insulation film 5a; or the threshold adjustment layer 8a is removed with the metal nitride film 7 by the wet etching step of the metal nitride film 7 described by reference to FIG. 10.

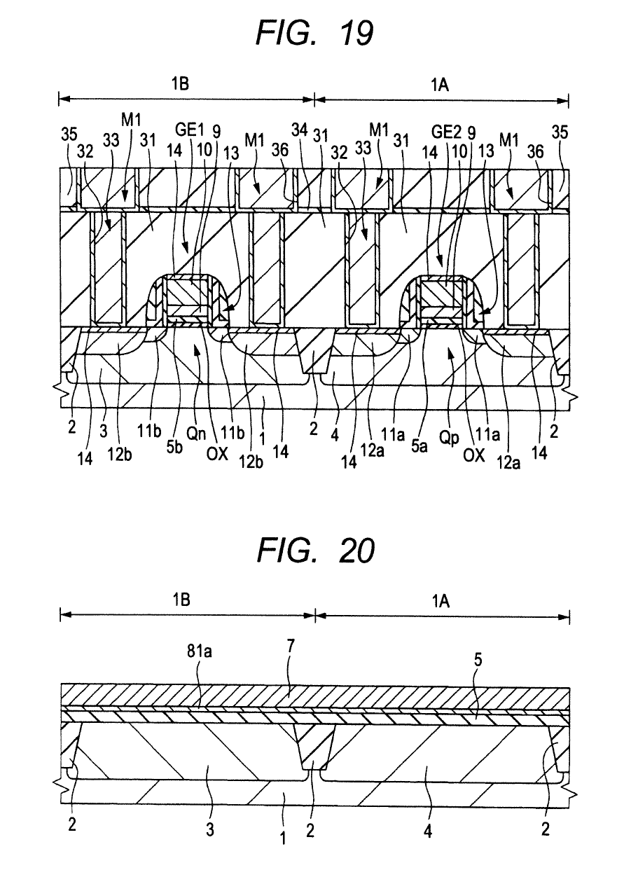

Namely, the threshold adjustment layer 8a is introduced into the Hf- and Al-containing insulation film 5a, or is removed with the metal nitride film 7 by the wet etching step. In such a case, after the wet etching step described by reference to FIG. 10, as shown in FIG. 18, over the Hf- and Al-containing insulation film 5a, the threshold adjustment layer 8a is not formed, and over the Hf- and Ln-containing insulation film 5b, the threshold adjustment layer 8b is not formed. The subsequent steps are performed in the same manner as the steps shown in FIGS. 11 to 17. As a result, as shown in FIG. 19, there is completed a semiconductor device in which the p channel type MISFET Qp having a gate structure not including the threshold adjustment layer 8a, and the n channel type MISFET Qn are formed.

As described above, for the p channel type MISFET Qp, by increasing the work function, it is possible to reduce the threshold voltage. In the p channel type MISFET Qp, the threshold adjustment layer 8a including an aluminum film is present. Accordingly, the work function increases, which can reduce the threshold voltage. However, when Al in the threshold adjustment layer 8a is sufficiently introduced into the Hf- and Al-containing insulation film 5a, as shown in FIGS. 18 and 19, it does not matter if the threshold adjustment layer 8a over the Hf- and Al-containing insulation film 5a is not left.

Then, the features of the present embodiment will be described in more details.

In the present embodiment, the gate electrodes GE1 and GE2 of the n channel type MISFET Qn and the p channel type MISFET Qp shown in FIG. 17 have the metal films 9 situated over the gate insulation films (herein, the Hf- and Al-containing insulation film 5a and the Hf- and Ln-containing insulation film 5b), and are so-called metal gate electrodes. For this reason, it is possible to inhibit the depletion phenomenon of the gate electrode, and to eliminate the parasitic capacitance. This also enables miniaturization of MISFET elements (reduction of the thickness of the gate insulation film).

Further, in the present embodiment, as the gate insulation film of the n channel type MISFET Qn, there is used the Hf- and Ln-containing insulation film 5b having a higher dielectric constant than that of silicon oxide. As the gate insulation film of the p channel type MISFET Qp, there is used the Hf- and Al-containing insulation film 5a having a higher dielectric constant than that of silicon oxide. Namely, the Hf- and Ln-containing insulation film 5b and the Hf- and Al-containing insulation film 5a which are films of a material with a higher dielectric constant than that of silicon oxide, or so-called high-k films (high dielectric constant films) are used for the gate insulation films of the n channel type MISFET Qn and the p channel type MISFET Qp, respectively. For this reason, as compared with the case where for the gate insulation films of the n channel type MISFET Qn and the p channel type MISFET Qp, silicon oxide films are used, it is possible to increase the physical film thickness of the Hf- and Ln-containing insulation film 5b and the Hf- and Al-containing insulation film 5a. This can reduce the leakage current.

Further, in the present embodiment, for the gate insulation film of the p channel type MISFET Qp, the Hf- and Al-containing insulation film 5a is used. For the gate insulation film of the n channel type MISFET Qn, the Hf- and Ln-containing insulation film 5b is used. This enables the reduction of the absolute values of the threshold values (threshold voltages) of the n channel type MISFET Qn and the p channel type MISFET. Namely, as compared with the case where an insulation film not containing a rare earth element such as lanthanum as with the Hf-containing insulation film 5 (see FIG. 6) is used as the gate insulation film as distinct from the present embodiment, when for the gate insulation film of the n channel type MISFET Qn, the Hf- and Ln-containing insulation film 5b is used as in the present embodiment, it is possible to set a lower threshold value of the n channel type MISFET Qn. Whereas, as compared with the case where an insulation film not containing aluminum as with the Hf-containing insulation film 5 (see FIG. 6) is used as the gate insulation film as distinct from the present embodiment, when for the gate insulation film of the p channel type MISFET Qp, the Hf- and Al-containing insulation film 5a is used as in the present embodiment, it is possible to set a lower threshold value of the p channel type MISFET Qp.

The degree of reduction of the threshold value of the n channel type MISFET Qn due to inclusion of a rare earth element (particularly, lanthanum) in the Hf- and Ln-containing insulation film 5b can be controlled by the formed thickness of the threshold adjustment layer 8b described by reference to FIG. 7, the temperature of the heat treatment described by reference to FIG. 8, or the like. The higher the content of the rare earth element (particularly, lanthanum) in the Hf- and Ln-containing insulation film 5b is, the more the threshold value of the n channel type MISFET Qn can be reduced. Therefore, the formed thickness of the threshold adjustment layer 8b or the temperature of the heat treatment described by reference to FIG. 8 is increased. In addition, the content of the rare earth element (particularly, lanthanum) in the Hf- and Ln-containing insulation film 5b is increased. As a result, it is possible to more reduce the threshold value of the n channel type MISFET Qn. For this reason, it is possible to set the formed thickness of the threshold adjustment layer 8b or the temperature of the heat treatment described by reference to FIG. 8 according to the desirable threshold value of the n channel type MISFET Qn.

Similarly, the degree of reduction of the threshold value of the p channel type MISFET Qp due to inclusion of aluminum in the Hf- and Al-containing insulation film 5a can be controlled by the formed thickness of the threshold adjustment layer 8a described by reference to FIG. 4, the temperature of the heat treatment described by reference to FIG. 8, or the like. The higher the content of aluminum in the Hf- and Al-containing insulation film 5a is, the more the threshold value of the p channel type MISFET Qp can be reduced. Therefore, the formed thickness of the threshold adjustment layer 8a or the temperature of the heat treatment described by reference to FIG. 8 is increased. In addition, the content of aluminum in the Hf- and Al-containing insulation film 5a is increased. As a result, it is possible to more reduce the threshold value of the p channel type MISFET Qp. For this reason, it is possible to set the formed thickness of the threshold adjustment layer 8a or the temperature of the heat treatment described by reference to FIG. 8 according to the desirable threshold value of the p channel type MISFET Qp.

Further, in the present embodiment, it is one of main features that the threshold adjustment layer 8a and the threshold adjustment layer 8b are films each including a member scarcely containing oxygen. This will be described by way of comparison between the manufacturing steps of the semiconductor device of comparative example of FIGS. 20 to 29 and the manufacturing steps of the present embodiment of FIGS. 1 to 17.

FIGS. 20 to 29 are each an essential-part cross-sectional view of a semiconductor device of a comparative example during a manufacturing step. The manufacturing steps of the semiconductor device of the comparative example of FIGS. 20 to 29 are different from those of the present embodiment, and correspond to the case where in the nMIS formation region, the threshold adjustment layer containing lanthanum oxide is formed, and in the pMIS formation region, the threshold adjustment layer containing aluminum oxide is formed. Below, a description will be given to the manufacturing steps of the semiconductor device of the comparative example of FIGS. 20 to 29.

In the manufacturing steps of the semiconductor device of the comparative example, the same steps as those of FIGS. 1 and 3 of the present embodiment are performed, resulting in the same structure as that of FIG. 3. Then, without forming the threshold adjustment layer 8a including an aluminum film scarcely containing oxygen as described by reference to FIG. 4 of the present embodiment, instead, as shown in FIG. 20, over the main surface of the semiconductor substrate 1, namely, over the Hf-containing insulation film 5, the threshold adjustment layer 81a including an aluminum oxide film is formed. However, in the comparative example, the silicon oxide film OX described by reference to FIG. 2 is not formed. Over the semiconductor substrate 1, the Hf-containing insulation film 5 is directly formed.

Incidentally, in the comparative example, there is not used the deposition/heat treatment apparatus 20 including the aluminum film deposition device 25 and the titanium nitride film deposition device 26 integrated with each other as described in FIG. 5. In the step shown in FIG. 20, by the aluminum oxide film deposition device, the threshold adjustment layer 81a is formed. Then, the semiconductor substrate 1 (semiconductor wafer) is extracted from the aluminum oxide film deposition device, and is transferred into the titanium nitride film deposition device. When extracted from the aluminum oxide film deposition device, the semiconductor wafer is exposed to the atmosphere. Therefore, even when the threshold adjustment layer 81a includes not an oxide but, for example, an aluminum film, the threshold adjustment layer 81a is oxidized by being exposed to the atmosphere.

Then, over the main surface of the semiconductor substrate 1, namely, over the threshold adjustment layer 81a, a metal nitride film 7 is formed. The metal nitride film 7 is a conductive film including, for example, TiN (titanium nitride).

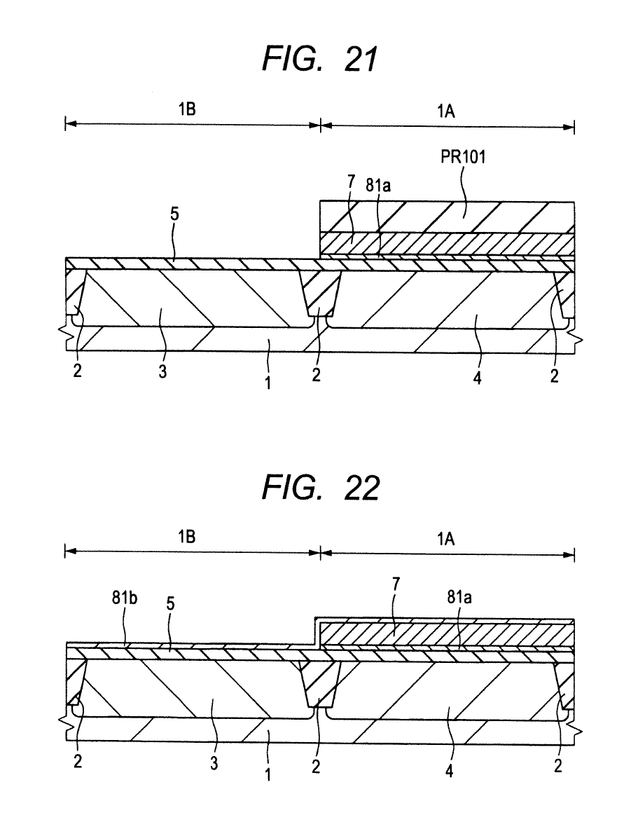

Then, as with the step shown in FIG. 6, over the main surface of the semiconductor substrate 1, namely, over the metal nitride film 7, a photoresist film is applied. The photoresist film is exposed and developed. As a result, over the metal nitride film 7 in the pMIS formation region 1A, a photoresist pattern (resist pattern) PR101 is formed as a resist pattern. Then, using the photoresist pattern PR101 as an etching mask, the metal nitride film 7 and the threshold adjustment layer 81a are wet etched, resulting in the structure shown in FIG. 21. By the wet etching step, portions of the metal nitride film 7 and the threshold adjustment layer 81a in the nMIS formation region 1B are etched and removed. However, portions of the metal nitride film 7 and the threshold adjustment layer 81a in the pMIS formation region 1A are covered with the photoresist pattern PR101, and hence are left without being etched.

Then, as with the step shown in FIG. 7, the photoresist pattern PR101 is removed. Then, over the main surface of the semiconductor substrate 1, a threshold adjustment layer 81b is formed, resulting in the structure of FIG. 22. Herein, the threshold adjustment layer 81b is formed over the Hf-containing insulation film 5 in the nMIS formation region 1B, and formed over the metal nitride film 7 in the pMIS formation region 1A. The threshold adjustment layer 81b is an oxide film containing a rare earth element Ln (in particular preferably, La). However, herein, a description will be given assuming that the threshold adjustment layer 81b includes a lanthanum oxide film.

Then, as with the step shown in FIG. 8, the semiconductor substrate 1 is subjected to a heat treatment. The heat treatment step is performed at a heat treatment temperature within the range of 780 to 850° C. As a result, in the nMIS formation region 1B, the Hf-containing insulation film 5 and the threshold adjustment layer 81b are allowed to react with each other. In the pMIS formation region 1A, the Hf-containing insulation film 5 and the threshold adjustment layer 81a are allowed to react with each other. Namely, by the heat treatment, aluminum forming the threshold adjustment layer 81a and lanthanum forming the threshold adjustment layer 81b are introduced (diffused) into portions of the Hf-containing insulation film 5 in the pMIS formation region 1A and the nMIS formation region 1B, respectively.

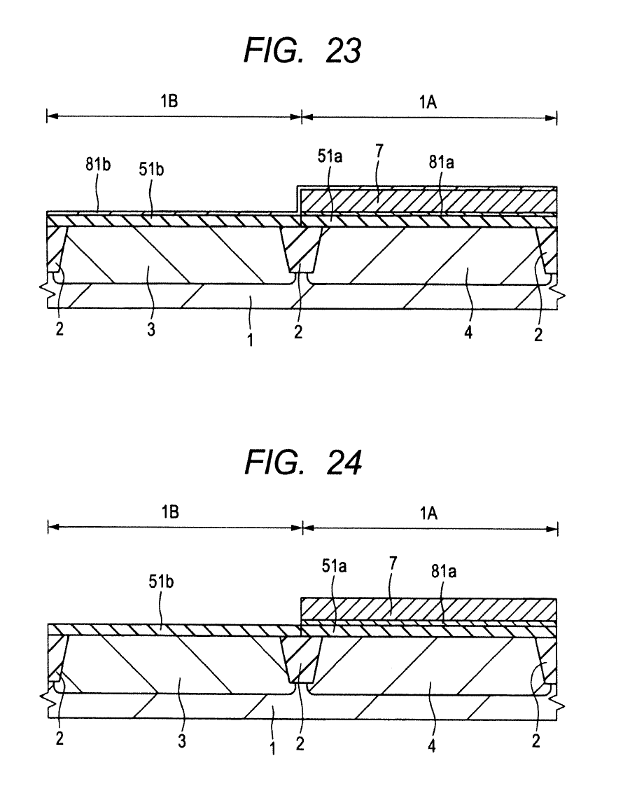

However, in the comparative example, the threshold adjustment layer 81a over the Hf-containing insulation film 5 in the pMIS formation region 1A includes an aluminum oxide film. The threshold adjustment layer 81b over the Hf-containing insulation film 5 in the nMIS formation region 1B includes a lanthanum oxide film. For this reason, in the heat treatment step, into the Hf-containing insulation film 5 in the nMIS formation region 1B and the pMIS formation region 1A, not only lanthanum or aluminum but also oxygen are introduced from the threshold adjustment layers 81a and 81b. Accordingly, into the Hf-containing insulation film 5 in the pMIS formation region 1A shown in FIG. 22, aluminum and oxygen are introduced, resulting in the Hf-containing insulation film 51a containing aluminum and oxygen. Into the Hf-containing insulation film 5 in the nMIS formation region 1B shown in the FIG. 22, lanthanum and oxygen are introduced, resulting in the Hf-containing insulation film 51b containing lanthanum and oxygen. As a result, the structure shown in FIG. 23 is obtained.

Incidentally, in the comparative example, there is not used the deposition/heat treatment apparatus 20 including the lanthanum film deposition device 27 and the annealing device 28 integrated with each other as shown in FIG. 5. In the step of FIG. 22, by the lanthanum oxide film deposition device, the threshold adjustment layer 81b is formed. Then, the semiconductor substrate 1 (semiconductor wafer) is extracted from the lanthanum oxide film deposition device, and is transferred into the annealing device for use in the step shown in FIG. 23. When extracted from the lanthanum oxide film deposition device, the semiconductor wafer is exposed to the atmosphere. Therefore, even when the threshold adjustment layer 81b includes not an oxide but, for example, a lanthanum film, the threshold adjustment layer 81b is oxidized by being exposed to the atmosphere.

Incidentally, the lanthanum film which is not an oxide has a higher hygroscopic property than that of a lanthanum oxide film. For example, the lanthanum film has a property of adsorbing moisture in the atmosphere, and being altered upon being exposed to the atmosphere. When the lanthanum film is thus altered, defects occur in the surface of the Hf-series gate insulation film formed under the lanthanum film. This may reduce the reliability of the semiconductor device. For this reason, in this comparative example, as the material for the threshold adjustment layer 81b, the lanthanum oxide film is used.

Then, as with the step shown in FIG. 9, the threshold adjustment layer 81b not reacted in the heat treatment step described by reference to FIG. 23 (unreacted threshold adjustment layer 81b) is removed by wet etching. Accordingly, the Hf-containing insulation film 51b and the metal nitride film 7 are exposed, resulting in the structure shown in FIG. 24.

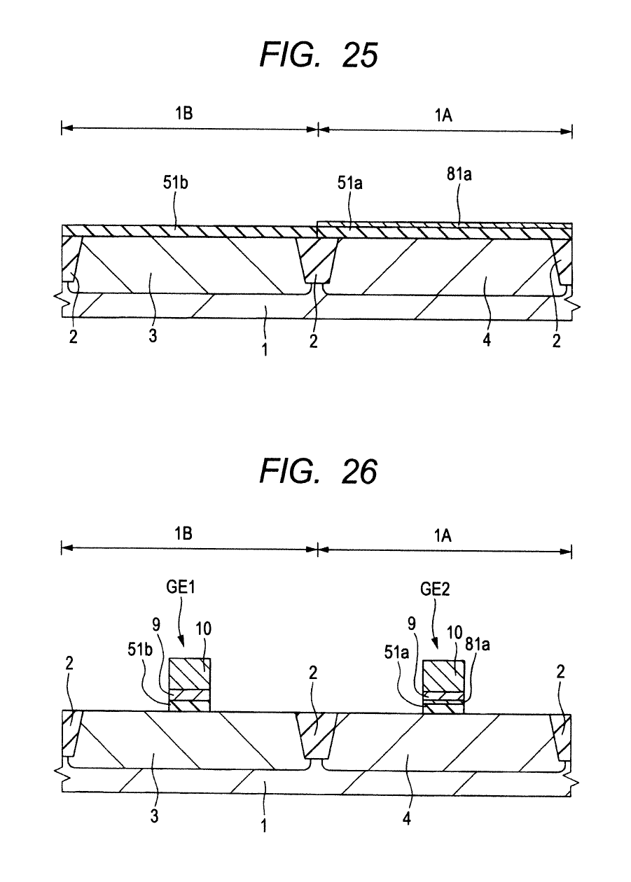

Then, as with the step shown in FIG. 10, the metal nitride film 7 is removed by wet etching. Accordingly, the metal nitride film 7 formed in the pMIS formation region 1A is removed. As a result, as shown in FIG. 25, the threshold adjustment layer 81a in the pMIS formation region 1A is exposed.

Herein, in the nMIS formation region 1B, with the Hf-containing insulation film 51b exposed, the wet etching step of the metal nitride film 7 is performed. However, the Hf-containing insulation film 51b has a low resistance to a chemical for use in wet etching (e.g., APM solution or hydrofluoric acid), and hence may be damaged by wet etching.

The metal nitride film 7 is more difficult to remove by wet etching when containing oxygen as in the comparative example than when scarcely containing oxygen as in the present embodiment. Therefore, when the metal nitride film 7 contains oxygen in a large amount as in the comparative example, a longer time is taken to remove the metal nitride film 7 by wet etching as compared with the present embodiment. When wet etching is thus performed over a long time, the Hf-containing insulation film 51b having a low resistance to a chemical for use in wet etching suffers a larger damage.

In contrast, in the present embodiment, the threshold adjustment layer 8a shown in FIG. 8 is assumed to be a layer scarcely containing oxygen. This prevents the introduction of oxygen from the inside of the threshold adjustment layer 8a into the metal nitride film 7. Therefore, oxygen is not introduced into the metal nitride film 7. Accordingly, the metal nitride film 7 can be removed in a short time with ease by wet etching. This can inhibit or prevent the etching damage inflicted on the Hf- and Ln-containing insulation film 5b in the wet etching step.

Then, as shown in FIG. 26, over the main surface of the semiconductor substrate 1, a metal film 9 for metal gate, and a silicon film 10 are sequentially formed. Then, the lamination film of the silicon film 10 and the metal film 9 is patterned using a photolithography technology and a dry etching technology. As a result, the gate electrodes GE1 and GE2 are formed.

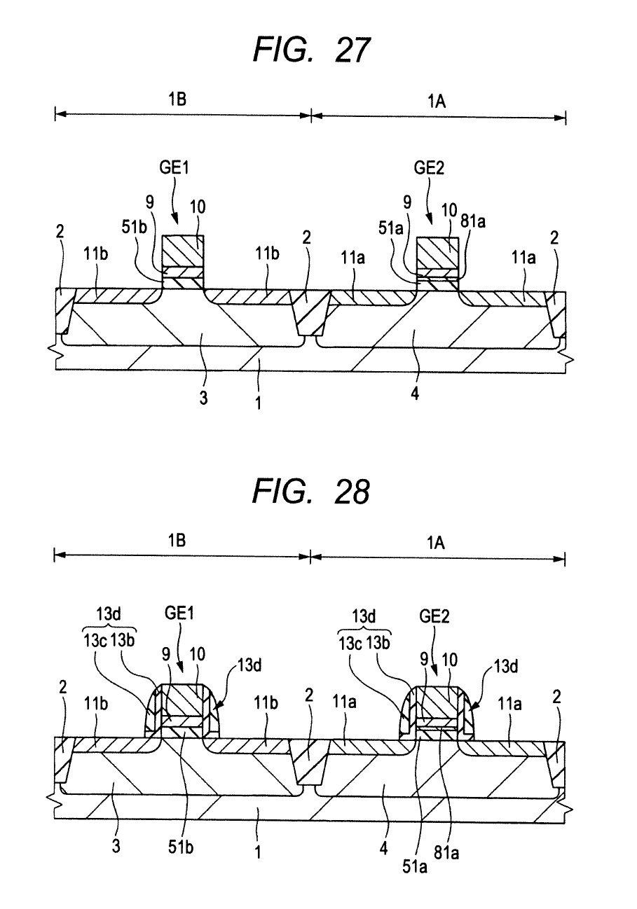

Then, as with the step shown in FIG. 13, into regions of the p type well 3 on the opposite sides of the gate electrode GE1 in the nMIS formation region 1B, n type impurities such as phosphorus (P) or arsenic (As) are ion-implanted. Accordingly, n⁻ type semiconductor regions 11b are formed. Whereas, into regions of the n type well 4 on the opposite sides of the gate electrode GE2 in the pMIS formation region 1A, p type impurities such as boron (B) are ion-implanted. Accordingly, the p⁻ type semiconductor regions 11a are formed. As a result, the structure shown in FIG. 27 is obtained.

Then, as shown in FIG. 28, over the sidewalls of the gate electrodes GE1 and GE2, sidewalls including an insulator (sidewall spacers or sidewall insulation films) 13d are formed. For example, over the semiconductor substrate 1, the silicon oxide film 13b and the silicon nitride film 13c are formed sequentially from the bottom in such a manner as to cover the gate electrodes GE1 and GE2. The lamination film of the silicon oxide film 13b and the silicon nitride film 13c is anisotropically etched (etched back). As a result, there are formed the sidewalls 13d including the silicon oxide film 13b and the silicon nitride film 13c left over the sidewalls of the gate electrodes GE1 and GE2.

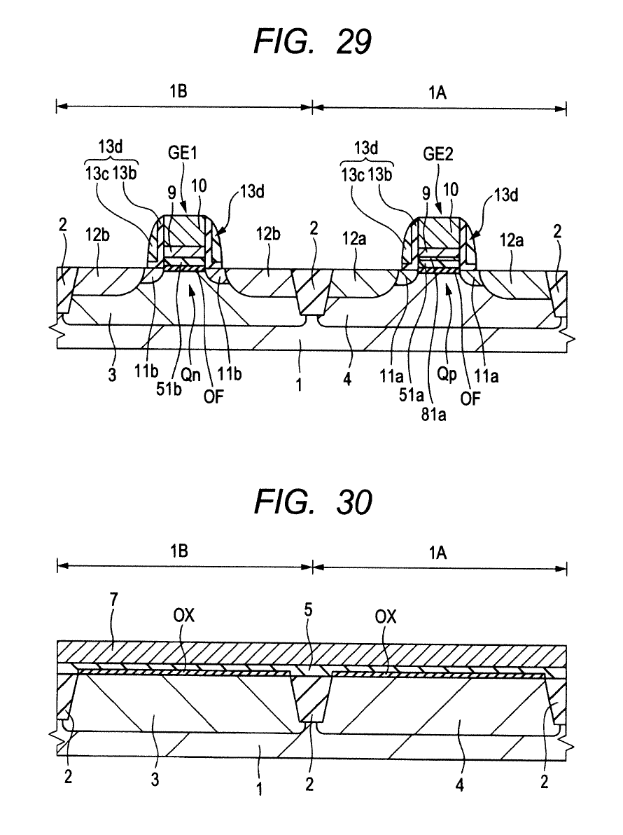

Then, as shown in FIG. 29, into regions of the p type well 3 on the opposite sides of the gate electrode GE1 and the sidewalls 13d in the nMIS formation region 1B, n type impurities such as phosphorus (P) or arsenic (As) are ion-implanted. Accordingly, the n⁺ type semiconductor regions 12b (source and drain) are formed. Whereas, into regions of the n type well 4 on the opposite sides of the gate electrode GE2 and the sidewalls 13d in the pMIS formation region 1A, p type impurities such as boron (B) are ion-implanted. Accordingly, the p⁺ type semiconductor regions 12a (source and drain) are formed.

After ion implantation, an annealing treatment (activation annealing or heat treatment) at about 1000° C. is performed for activation of the introduced impurities. As a result, it is possible to activate the impurities introduced into the n⁻ type semiconductor regions 11b, the p⁻ type semiconductor regions 11a, the n⁺ type semiconductor regions 12b, the p⁺ type semiconductor regions 12a, and the like.

By the annealing treatment for activation of the source/drain regions, at respective portions of the main surface of the semiconductor substrate 1 underlying the Hf-containing insulation film 51a and the Hf-containing insulation film 51b, insulation films OF including a silicon oxide film are respectively formed.

The insulation film OF formed in the nMIS formation region 1B is a silicon oxide film formed from combination of oxygen atoms diffused from respective insides of the silicon oxide film 13b forming the sidewalls 13d, and in contact with the Hf-containing insulation film 51b and the threshold adjustment layer 81b (see FIG. 23) through the Hf-containing insulation film 51b into the top surface of the semiconductor substrate 1, and silicon in the top surface of the semiconductor substrate 1 by the annealing treatment.

Further, the insulation film OF formed in the pMIS formation region 1A is a silicon oxide film formed from combination of oxygen atoms diffused from respective insides of the silicon oxide film 13b forming the sidewalls 13d, and in contact with the Hf-containing insulation film 51b and the threshold adjustment layer 81a through the Hf-containing insulation film 51a into the top surface of the semiconductor substrate 1, and silicon in the top surface of the semiconductor substrate 1 by the annealing treatment.

Incidentally, at this step, into the metal nitride film 7, oxygen is introduced from the threshold adjustment layers 81a and 81b, and the silicon oxide film 13b in contact with the surface of the metal nitride film 7.

The subsequent steps are the same as the steps of FIGS. 16 and 17.

It has been revealed from a study by the present inventors that in the manufacturing steps of the semiconductor device of the comparative example of FIGS. 20 to 29, the following problems occur.

Namely, when as the threshold adjustment layer, a film including lanthanum oxide or aluminum oxide which is an oxide film is used as in the comparative example, the oxygen in the threshold adjustment layer is diffused into a portion of the main surface of the semiconductor substrate underlying the threshold adjustment layer. Even when a silicon oxide film is formed between the threshold adjustment layer and the semiconductor substrate, oxygen may be introduced through the silicon oxide film into the main surface of the semiconductor substrate.

Accordingly, when oxygen is introduced from the threshold adjustment layer into the top surface of the semiconductor substrate, the oxygen and the silicon forming the semiconductor substrate form a compound. As a result, at the top surface of the semiconductor substrate, the insulation film OF (see FIG. 29) including a silicon oxide film is formed. Formation of the insulation film OF results in an increase in film thickness of the silicon oxide film forming the gate insulation film. Therefore, the total equivalent oxide thickness of the gate insulation film increases, resulting in an increase in threshold voltages of the n channel type MISFET and the p channel type MISFET.

Further, as described above, the insulation film OF cannot be formed with a precisely adjusted film thickness as with the silicon oxide film OX shown in FIG. 2. Namely, it becomes difficult to control the increase in equivalent oxide thickness of the gate insulation film including the insulation film OF (see FIG. 29). This causes variations in threshold voltages of the MISFETs.

Further, the insulation film OF is difficult to form in a high density as with the silicon oxide film OX shown in FIG. 2. Thus, in the insulation film OF (see FIG. 29), a larger number of defects occur than in the silicon oxide film OX. For this reason, when the silicon oxide film OX is not formed, and the insulation film OF (see FIG. 29) is formed, the effect of preventing the occurrence of a leakage current between the gate electrode and the semiconductor substrate is smaller than when the silicon oxide film OX is formed.

As shown in FIG. 16, the silicon oxide films OX with a high density are formed between the Hf-containing insulation film 51a and the Hf-containing insulation film 51b which are high-k films, and the semiconductor substrate 1, respectively. In this case, even when the Hf-containing insulation film 51a and the Hf-containing insulation film 51b contain oxygen, oxygen is less likely to be diffused into the top surface of the semiconductor substrate 1. This is because the silicon oxide films OX have an action of reducing the amount of oxygen to be diffused from the Hf-containing insulation film 51a and the Hf-containing insulation film 51b into the semiconductor substrate 1.

In contrast, in the comparative example, before the formation of the Hf-containing insulation film 5 shown in FIG. 19, the silicon oxide film OX shown in FIG. 2 is not formed. For this reason, in the heat treatment step described by reference to FIG. 29, the insulation film OF tends to be formed at the main surface of the semiconductor substrate 1.

The silicon oxide film is a film having a lower dielectric constant than that of the high-k film. Therefore, when as a part of the gate insulation film, a silicon oxide film such as the insulation film OF is formed, the value of the equivalent oxide thickness is higher than when the gate insulation film includes only a high-k film.

A description was given to the case where in the manufacturing steps of the semiconductor device shown in FIGS. 20 to 29, in the pMIS formation region 1A, the threshold adjustment layer 81a was left. However, even when the threshold adjustment layer 81a is removed as described by reference to FIGS. 18 and 19, oxygen is introduced into the Hf-containing insulation film 51a and a part underlying the Hf-containing insulation film 51a. For this reason, as described above, the threshold voltage of the p channel type MISFET Qp unfavorably increases.

Further, as described by reference to the comparative example, when a threshold adjustment layer containing a large amount of oxygen is used, oxygen is diffused from the threshold adjustment layer into the high-k film. However, when at the interface between the sidewall formed over each sidewall of the gate electrode and the high-k film or the threshold adjustment layer, an oxide film such as a silicon oxide film forming the sidewall is in contact with the high-k film or the threshold adjustment layer, oxygen is also introduced from the sidewall into the high-k film. Namely, as shown in FIG. 29, the silicon oxide films 13b faulting the sidewalls 13d are in direct contact with the Hf-containing insulation film 51a and the Hf-containing insulation film 51b which are high-k films, respectively. Therefore, oxygen is introduced from the inside of the silicon oxide film 13b into the Hf-containing insulation film 51a and the Hf-containing insulation film 51b. The oxygen forms the insulation film OF.

In other words, when an oxygen-rich threshold adjustment layer is used, oxygen in the threshold adjustment layer is introduced via the high-k film into the top surface of the semiconductor substrate. Thus, the silicon in the top surface of the semiconductor substrate is oxidized. As a result, at the interface between the top surface of the semiconductor substrate and the high-k film, an insulation film including a silicon oxide film is formed. In this case, the equivalent oxide thickness of the gate insulation film increases, so that the threshold value of the MISFET increases. Therefore, it becomes difficult to achieve miniaturization, a higher speed, or a lower power consumption of the semiconductor device.

Further, it is difficult to control the film thickness of the insulation film at the interface between the top surface of the semiconductor substrate and the high-k film formed by the oxygen diffused from the threshold adjustment layer, the sidewalls, or the like. This causes variations in threshold voltages of the MISFETs, which adversely affects the characteristics or the reliability of the semiconductor device.

In contrast, in the present embodiment, a film scarcely containing oxygen is used as the threshold adjustment layer. This prevents diffusion of oxygen from the threshold adjustment layer into the semiconductor substrate. Namely, as shown in FIG. 7, in the nMIS formation region 1B, there is formed the threshold adjustment layer 8b not containing oxygen, and mainly containing lanthanum; and in the pMIS formation region 1A, there is formed the threshold adjustment layer 8a not containing oxygen and mainly containing aluminum. This can prevent diffusion of oxygen from the threshold adjustment layers 8a and 8b into the semiconductor substrate 1. As a result, it is possible to prevent the formation of the insulation film OF (see FIG. 29) over the semiconductor substrate 1, which can prevent the increase in threshold voltages of the n channel type MISFET Qn and the p channel type MISFET Qp.

However, as described by reference to FIG. 4, after formation of the threshold adjustment layer 8a, over the threshold adjustment layer 8a, the metal nitride film 7 is formed. In this step, the semiconductor substrate 1 (semiconductor wafer) is extracted from the inside of the device for forming the threshold adjustment layer 8a. The semiconductor wafer is transferred into the device for forming the metal nitride film 7. At this step, when the semiconductor wafer is exposed to the atmosphere, the threshold adjustment layer 8a including an aluminum film may be oxidized by oxygen, moisture, or the like in the atmosphere. Similarly, as described by reference to FIGS. 7 and 8, the threshold adjustment layer 8b including a lanthanum film or the like is formed. Then, when the semiconductor substrate 1 is subjected to a heat treatment, the semiconductor wafer is extracted from the device for forming the threshold adjustment layer 8b. The semiconductor wafer is transferred into the annealing device. At this step, when the semiconductor wafer is exposed to the atmosphere (subjected to atmosphere exposure), the threshold adjustment layer 8b may be oxidized.

Namely, after formation of the threshold adjustment layer 8a, over the threshold adjustment layer 8a, the metal nitride film 7 is formed. At this step, when the semiconductor wafer is exposed to the atmosphere, the threshold adjustment layer 8a is oxidized. This reduces the effect of preventing the introduction of oxygen into the top surface of the semiconductor substrate 1 by using an aluminum film scarcely containing oxygen for the threshold adjustment layer 8a. Whereas, when the semiconductor substrate 1 is subjected to a heat treatment after the formation of the threshold adjustment layer 8b, the semiconductor wafer is exposed to the atmosphere. As a result, the threshold adjustment layer 8b is oxidized. This reduces the effect of preventing the introduction of oxygen into the top surface of the semiconductor substrate 1 by using a lanthanum film scarcely containing oxygen or the like for the threshold adjustment layer 8b.

In contrast, in the present embodiment, there is used a manufacturing apparatus including a device for forming the threshold adjustment layer 8a and a device for forming the metal nitride film 7 in an integral form, and including an inert gas atmosphere in the inside thereof (see FIG. 5). This prevents the threshold adjustment layer 8a from being exposed to the atmosphere. Further, by using the manufacturing apparatus including a device for forming the threshold adjustment layer 8b, and an annealing device for heat-treating the semiconductor substrate in an integral form as shown in FIG. 5, the threshold adjustment layer 8b is prevented from being exposed to the atmosphere. This can prevent the oxidation of the threshold adjustment layers 8a and 8b.

Further, as described above, the lanthanum film has a higher hygroscopic property than that of a lanthanum oxide film. Thus, upon being exposed to the atmosphere, the lanthanum film unfavorably adsorbs moisture and is altered, and thereby causes defects in the surface of the Hf-series gate insulation film. However, in the present embodiment, in the deposition step and annealing step described by reference to FIGS. 7 and 8, the deposition/heat treatment apparatus 20 shown in FIG. 5 is used. This can prevent the threshold adjustment layer including a lanthanum film from being exposed to the atmosphere. Therefore, it is possible to prevent the degradation of the reliability of the semiconductor device due to the moisture absorption of the lanthanum film.

Further, in the present embodiment, as described by reference to FIG. 14, when the sidewalls 13 are formed, in order to prevent the silicon oxide films 13b forming the sidewalls 13 from being in direct contact with the threshold adjustment layer 8a, and the Hf- and Al-containing insulation film 5a or the Hf- and Ln-containing insulation film 5b, the silicon nitride films 13a are formed between the silicon oxide films 13b and the gate electrode GE1, and between the silicon oxide films 13b and the gate electrode GE2, respectively. Thus, the oxygen-containing silicon oxide film 13b is prevented from being in direct contact with the threshold adjustment layer 8a, and the Hf- and Al-containing insulation film 5a or the Hf- and Ln-containing insulation film 5b. This prevents oxygen in the silicon oxide films 13b from being diffused via the threshold adjustment layer 8a, and the Hf- and Al-containing insulation film 5a or the Hf- and Ln-containing insulation film 5b into the semiconductor substrate 1.

In other words, in the present embodiment, into the high-k film forming the gate insulation film, a rare earth element or aluminum is introduced to adjust the threshold value of the MISFET. At this step, the threshold adjustment layer scarcely containing oxygen is used. Accordingly, oxygen is prevented from being diffused into the high-k film and the semiconductor substrate under the threshold adjustment layer. This prevents the formation of an insulation film including a silicon oxide film at the interface between the top surface of the semiconductor substrate and the high-k film. As a result, it is possible to prevent the increase in equivalent oxide thickness of the gate insulation film of each MISFET.

Incidentally, as described above, each amount of oxygen contained in the threshold adjustment layer 8a shown in FIG. 4 and the threshold adjustment layer 8b shown in FIG. 7 is set at 30 atomic % or less. The reason for this is as follows: each proportion of oxygen in the components in the threshold adjustment layers 8a and 8b is set at 30 atomic % or less; as a result, even when oxygen is diffused into the high-k film and the semiconductor substrate under the threshold adjustment layers 8a and 8b, the equivalent oxide thickness of the MISFET hardly increases; accordingly, the semiconductor device can be used without a problem.

Further, between the silicon oxide film forming each sidewall and the gate electrode, there is formed an insulation film (e.g., silicon nitride film) not containing oxygen. This prevents oxygen in the sidewall from being diffused into the semiconductor substrate via the high-k film.

In the present embodiment, by preventing the increase in equivalent oxide thickness of the gate insulation film due to the formation of the insulation film, the threshold voltage of the MISFET is prevented from increasing. This enables the improvement of the performances of the semiconductor device. Further, similarly, the insulation film is prevented from being formed at the top surface of the semiconductor substrate. This prevents variations in threshold voltages of the MISFETs, which enables the improvement of the reliability of the semiconductor device.

Further, as shown in FIG. 2, at the top surface of the semiconductor substrate, the silicon oxide film OX with a high density is formed by a heat treatment at about 1000° C. This prevents the occurrence of a leakage current between the gate electrode and the semiconductor substrate. Incidentally, the silicon oxide film OX can be formed with the film thickness and density easily controlled. Therefore, even when, as a part of the gate insulation film, the silicon oxide film OX is formed between the high-k film and the semiconductor substrate, the values of the threshold voltages of the MISFETs are not varied.

The formation of the silicon oxide film OX can prevent the following: by the heat treatment step for activating the source/drain regions described by reference to FIG. 15, at the top surface of the semiconductor substrate under the gate electrode, an insulation film including a silicon oxide film (corresponding to the insulation film OF shown in FIG. 29) is formed. Further, the formation of the silicon oxide film OX can inhibit the diffusion of oxygen in the high-k film into the semiconductor substrate even when oxygen is introduced into the high-k film over the silicon oxide film OX. This is because the silicon oxide film OX with a high density has a low oxygen permeability.

Further, in the present embodiment, oxygen is not contained in the threshold adjustment layer. This prevents the introduction of oxygen into a metal film (corresponding to the metal nitride film 7 shown in FIG. 4) formed as a hard mask over the threshold adjustment layer. As a result, as compared with the case where oxygen is introduced into the metal film, the metal film becomes more likely to be removed by etching, and can be removed by an etching treatment for a relatively short time. In the etching step, when the high-k film to be the gate insulation film is exposed, the high-k film tends to be damaged by etching. Therefore, the etching treatment is preferably performed for a shorter time.

Namely, in the present embodiment, the threshold adjustment layer 8a shown in FIG. 4 is formed of an aluminum film scarcely containing oxygen. This prevents the introduction of oxygen into the metal nitride film 7. As a result, it becomes possible to remove the metal nitride film 7 for a short time in the subsequent step. Therefore, it is possible to prevent the Hf- and Ln-containing insulation film 5b in the nMIS formation region 1B from being damaged by wet etching. This can improve the reliability of the semiconductor device.

Further, as shown in FIG. 17, when between the Hf- and Al-containing insulation film 5a and the metal film 9, the threshold adjustment layer 8a including an aluminum film is left, aluminum is diffused into the metal film 9 including, for example, TiN. This results in an increase in work function of the p channel type MISFET, which can reduce the threshold voltage of the p channel type MISFET.

Incidentally, as described above, when the threshold adjustment layer 81b includes an oxide film of a rare earth element as with the comparative example described by reference to FIGS. 20 to 29, the amount of oxygen to be diffused into the high-k film and into the semiconductor substrate is too large. Accordingly, the threshold voltage of the CMISFET unfavorably increases. In contrast, in the present embodiment, oxygen is prevented from being introduced into the high-k film forming the gate insulation film and the semiconductor substrate. This prevents the increase in threshold voltage of the CMISFET, which can enhance the performances of the semiconductor device.

On the other hand, for the purpose of further enhancing the reliability of the semiconductor device, oxygen is preferably introduced in a small amount into the high-k film (Hf-series gate insulation film). This is for the following reason: the Hf-series gate insulation film containing lanthanum oxide including oxygen has a feature of being less likely to have defects such as voids formed in the inside thereof than the Hf-series gate insulation film including a film not containing oxygen such as a lanthanum film. For example, when in the Hf-series gate insulation film not containing oxygen, voids are formed, portions of the gate electrode formed over the Hf-series gate insulation film are filled in the voids of the Hf-series gate insulation film. Thus, a leakage current may occur via the portions of the gate electrode in the voids of the Hf-series gate insulation film between the gate electrode and a portion of the semiconductor substrate underlying the Hf-series gate insulation film.

In contrast, the Hf-series gate insulation film containing oxygen is less likely to have defects such as voids formed in the inside thereof, and hence has a high reliability as the gate insulation film. Therefore, in order to prevent the occurrence of a leakage current between the gate electrode and the semiconductor substrate, and improve the reliability of the semiconductor device, it is preferable that oxygen is appropriately introduced into the Hf-series gate insulation film. However, when the threshold adjustment layer 81b including, for example, a lanthanum oxide film is used as in the comparative example described by reference to FIGS. 20 to 29, the amount of oxygen to be diffused into the Hf-series gate insulation film and the semiconductor substrate is too large. For this reason, as described above, at the top surface of the semiconductor substrate, an insulation film including silicon oxide is formed. This unfavorably reduces the reliability of the semiconductor device. Accordingly, in order to introduce a small amount of oxygen into the Hf-series gate insulation film, it is necessary to properly control the amount of oxygen to be introduced into the threshold adjustment film.

As the method for introducing a small amount of oxygen into the Hf-series gate insulation film, there is the following method: for example, in the deposition step described by reference to FIG. 7, the threshold adjustment layer 8b including, for example, a lanthanum film is formed; then, a portion of the threshold adjustment layer 8b is oxidized in a low-pressure atmosphere including oxygen; then, the inside of the deposition/heat treatment apparatus 20 (see FIG. 5) for use in the heat treatment step shown in FIG. 8 is set under a low-pressure atmosphere containing oxygen; thus, the semiconductor substrate is heated. As a result, a small amount of oxygen is introduced from the lanthanum oxide film formed in the threshold adjustment layer 8b into the Hf-series gate insulation film (corresponding to the Hf- and Ln-containing insulation film 5b of FIG. 8). This prevents the formation of defects in the Hf-series gate insulation film, which can improve the reliability of the semiconductor device.

Incidentally, also when a small amount of oxygen is thus introduced into the Hf-series gate insulation film, in order to adjust the proportion of the threshold adjustment layer to be oxidized, the following are desirable: in the steps shown in FIGS. 7 and 8, there is used the deposition/heat treatment apparatus 20 in which the lanthanum film deposition device 27 and the annealing device 28 are integrally formed as shown in FIG. 5; in the manufacturing step, the inside of the deposition/heat treatment apparatus 20 is set under an inert gas atmosphere; and during transfer of the semiconductor wafer, the semiconductor wafer is prevented from being exposed to the atmosphere.

The Hf-series gate insulation film containing a small amount of oxygen formed by the step is very lower in amount of oxygen introduced than the Hf-containing insulation film 51b in the comparative example shown in FIGS. 20 to 29. For this reason, even when a small amount of oxygen is introduced into the Hf-series gate insulation film, it is possible to prevent the increase in threshold voltage of the CMISFET due to the introduction of oxygen into the semiconductor substrate described by reference to the comparative example.

### Second Embodiment

In the first embodiment, a description was given to the method for manufacturing a semiconductor device in which in both of the nMIS formation region and the pMIS formation region, the threshold adjustment layers were formed. In the present second embodiment, a description will be given to a method for manufacturing a semiconductor device in which in the pMIS formation region, the threshold adjustment layer is not formed, and only in the nMIS formation region, the threshold adjustment layer is formed.

FIGS. 30 to 38 are each an essential-part cross-sectional view of the semiconductor device of the present second embodiment during a manufacturing step.

The manufacturing steps of the present embodiment are, as described by reference to FIG. 3, the same as the manufacturing steps of the first embodiment up to the formation of the Hf-containing insulation film 5. Therefore, herein, a description thereon is omitted, and the metal nitride film formation step and subsequent steps will be described.

After performing the same steps as the steps shown in FIGS. 1 to 3 of the first embodiment, in the present embodiment, as shown in FIG. 30, over the main surface of the semiconductor substrate 1, namely, over the Hf-containing insulation film 5, the metal nitride film 7 is formed as a hard mask. The metal nitride film 7 is a film including, for example, TiN (titanium nitride).

Incidentally, herein, the threshold adjustment layer 8a shown in FIG. 4 is not formed. Therefore, as distinct from the first embodiment, it is not necessary to prevent the threshold adjustment layer 8a from being exposed to the atmosphere. For this reason, it is not necessary to use the deposition/heat treatment apparatus 20 including the aluminum film deposition device 25 and the titanium nitride film deposition device 26 in an integral form as shown in FIG. 5.

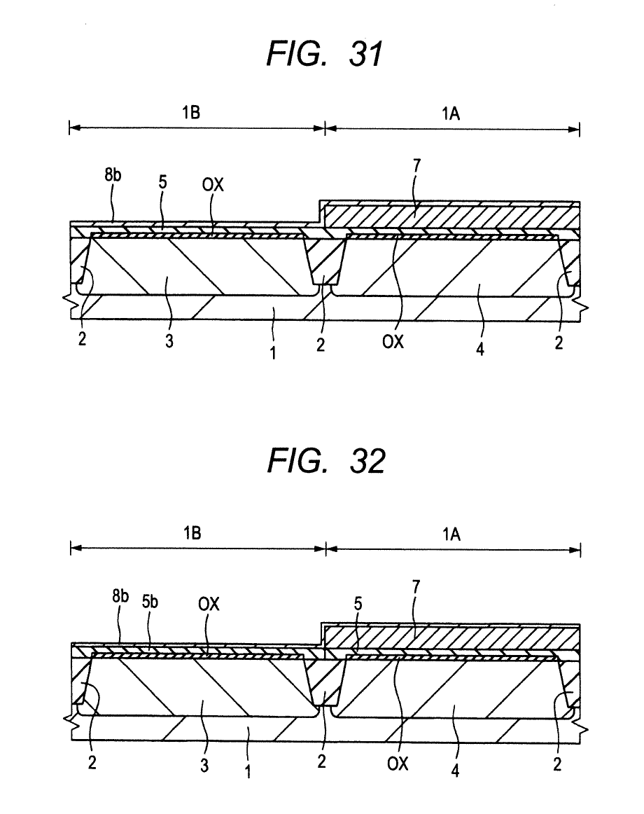

Then, as shown in FIG. 31, by etching using a photolithography technology, the metal nitride film 7 in the nMIS formation region 1B is removed. Then, over the main surface of the semiconductor substrate 1, the threshold adjustment layer (first metal element-containing layer) 8b is formed. Herein, the threshold adjustment layer 8b is formed over the Hf-containing insulation film 5 in the nMIS formation region 1B, and is formed over the metal nitride film 7 in the pMIS formation region 1A.

As in the first embodiment, the threshold adjustment layer 8b contains a rare earth element, and in particular preferably, contains La (lanthanum). The threshold adjustment layer 8b can be formed by a sputtering method or the like. The film thickness (deposited film thickness) can be set at about 1 nm. However, the threshold adjustment layer 8b preferably scarcely contains oxygen, and contains oxygen in an amount of only 30 atomic % at most, and is assumed to be a film mainly including lanthanum (La). Namely, the threshold adjustment layer 8a scarcely contains lanthanum oxide (e.g., La₂O₃).

Incidentally, in the formation step of the threshold adjustment layer 8b, there is used the deposition/heat treatment apparatus 20 having the lanthanum film deposition device 27 and the annealing device 28 as shown in FIG. 5. The inside of the deposition/heat treatment apparatus 20 is set under an inert gas atmosphere.

Then, as shown in FIG. 32, the semiconductor substrate 1 is subjected to a heat treatment. The heat treatment step can be performed at a heat treatment temperature within the range of 780 to 850° C. in an inert gas atmosphere (e.g., N₂ (nitrogen) atmosphere). By the heat treatment, in the nMIS formation region 1B, the Hf-containing insulation film 5 and the threshold adjustment layer 8b are allowed to react with each other. Namely, by the heat treatment, the rare earth element Ln (in particular preferably, La) forming the threshold adjustment layer 8b is introduced (diffused) into a portion of the Hf-containing insulation film 5 in the nMIS formation region 1B.

In the heat treatment step, in the nMIS formation region 1B, the threshold adjustment layer 8b and the Hf-containing insulation film 5 are in contact with each other, and hence both are allowed to react with each other. As a result, the rare earth element Ln (in particular preferably, Ln=La) of the threshold adjustment layer 8b is introduced (diffused) into the Hf-containing insulation film 5. On the other hand, in the pMIS formation region 1A, the metal nitride film 7 is interposed between the threshold adjustment layer 8b and the Hf-containing insulation film 5. Thus, Ln in the threshold adjustment layer 8b is not introduced into the Hf-containing insulation film 5.

By the heat treatment, as shown in FIG. 32, in the nMIS formation region 1B, the threshold adjustment layer 8b and the Hf-containing insulation film 5 are allowed to react (are blended or mixed) to form the Hf- and Ln-containing insulation film 5b. The threshold adjustment layer 8b is not a rare earth oxide layer but a layer, almost entirely, mainly including a rare earth element. For this reason, oxygen (O) is scarcely introduced from the threshold adjustment layer 8b into the Hf-containing insulation film 5.

Incidentally, in the heat treatment step, there is used the annealing device 28 in the deposition/heat treatment apparatus 20 as shown in FIG. 5. Herein, the semiconductor substrate 1 (semiconductor wafer) over which the threshold adjustment layer 8b is formed as shown in FIG. 31 is transferred from the inside of the lanthanum film deposition device 27 shown in FIG. 5 into the annealing device 28 by the robot arm 23. By the annealing device 28, the heat treatment described by reference to FIG. 32 is performed. At this step, the inside of the deposition/heat treatment apparatus 20 is set under an inert gas atmosphere.

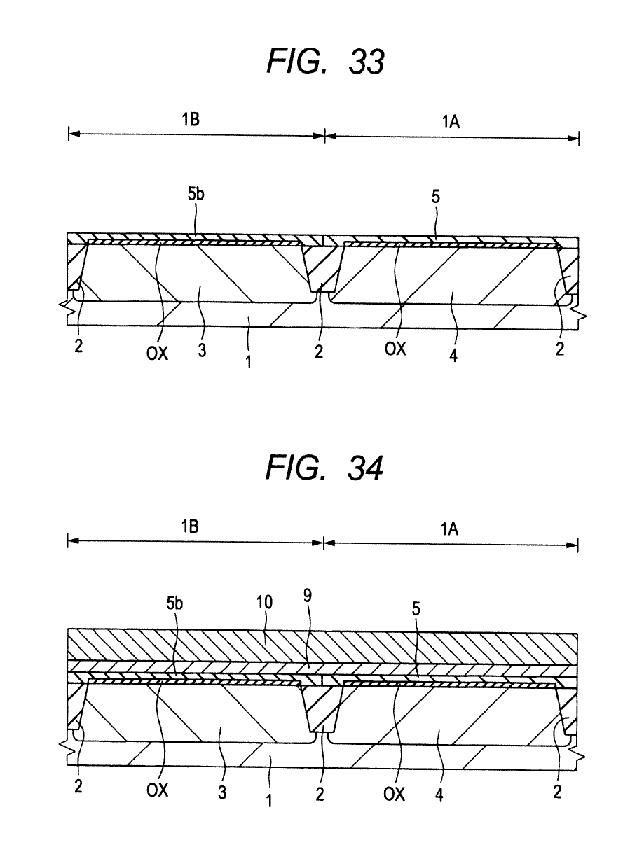

Then, as shown in FIG. 33, the threshold adjustment layer 8b (unreacted threshold adjustment layer 8b) not reacted in the heat treatment step described by reference FIG. 8 is removed by wet etching. Then, the metal nitride film 7 is removed by wet etching.

Herein, with the Hf- and Ln-containing insulation film 5b in the nMIS formation region 1B exposed, the wet etching step of the metal nitride film 7 is performed. However, the Hf- and Ln-containing insulation film 5b has a low resistance to a chemical for use in wet etching (e.g., APM solution or hydrofluoric acid), and hence may be damaged by wet etching.

The metal nitride film 7 is more difficult to remove by wet etching when containing oxygen than when not containing oxygen. Therefore, when the metal nitride film 7 contains oxygen in a larger amount, a longer time is taken to remove the metal nitride film 7 by wet etching. When wet etching is thus performed over a long time, the Hf- and Ln-containing insulation film 5b having a low resistance to a chemical for use in wet etching suffers a larger damage.

In contrast, in the present embodiment, the threshold adjustment layer 8b shown in FIG. 32 is assumed to be a layer scarcely containing oxygen. This prevents the introduction of oxygen from the inside of the threshold adjustment layer 8b into the metal nitride film 7. Accordingly, the metal nitride film 7 can be removed in a short time with ease by wet etching. This can inhibit or prevent the etching damage inflicted on the Hf- and Ln-containing insulation film 5b by the wet etching step.

Then, as shown in FIG. 34, over the main surface of the semiconductor substrate 1, the metal film (metal layer) 9 for metal gate (metal gate electrode) and the silicon film 10 are successively formed.

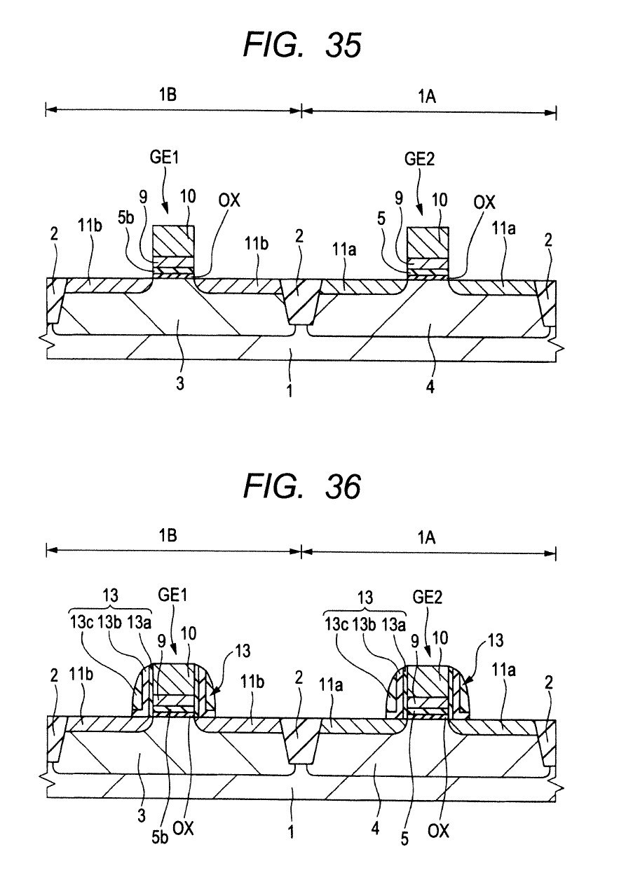

Then, as shown in FIG. 35, the lamination film of the silicon film 10 and the metal film 9 is patterned using a photolithography technology and a dry etching technology. This results in the formation of the gate electrodes GE1 and GE2 each including the metal film 9 and the silicon film 10 over the metal film 9.

The gate electrode GE1 is formed over the Hf- and Ln-containing insulation film 5b in the nMIS formation region 1B. The gate electrode GE2 is formed over the silicon oxide film OX in the pMIS formation region 1A.

Subsequently, as with the first embodiment, in regions of the p type well 3 on the opposite sides of the gate electrode GE1 in the nMIS formation region 1B, n⁻ type semiconductor regions (extension regions or LDD regions) 11b are formed. In regions of the n type well 4 on the opposite sides of the gate electrode GE2 in the pMIS formation region 1A, p⁻ type semiconductor regions (extension regions or LDD regions) 11a are formed.

Then, as shown in FIG. 36, over the sidewalls of the gate electrodes GE1 and GE2, sidewalls including an insulator (sidewall spacers or sidewall insulation films) 13 are formed. For example, over the semiconductor substrate 1, a silicon nitride film is formed in such a manner as to cover the gate electrodes GE1 and GE2. Then, the silicon nitride film is anisotropically etched (etched back). As a result, over respective sidewalls of the gate electrodes GE1 and GE2, the silicon nitride films 13a are left in a self-alignment manner. Subsequently, over the semiconductor substrate 1, a silicon oxide film 13b and a silicon nitride film 13c are formed sequentially from the bottom in such a manner as to cover the gate electrodes GE1 and GE2. Then, a lamination film of the silicon oxide film 13b and the silicon nitride film 13c is anisotropically etched (etched back). As a result, it is possible to form sidewalls 13 including the silicon nitride films 13a, the silicon oxide films 13b, and the silicon nitride films 13c left over the sidewalls of the gate electrodes GE1 and GE2.

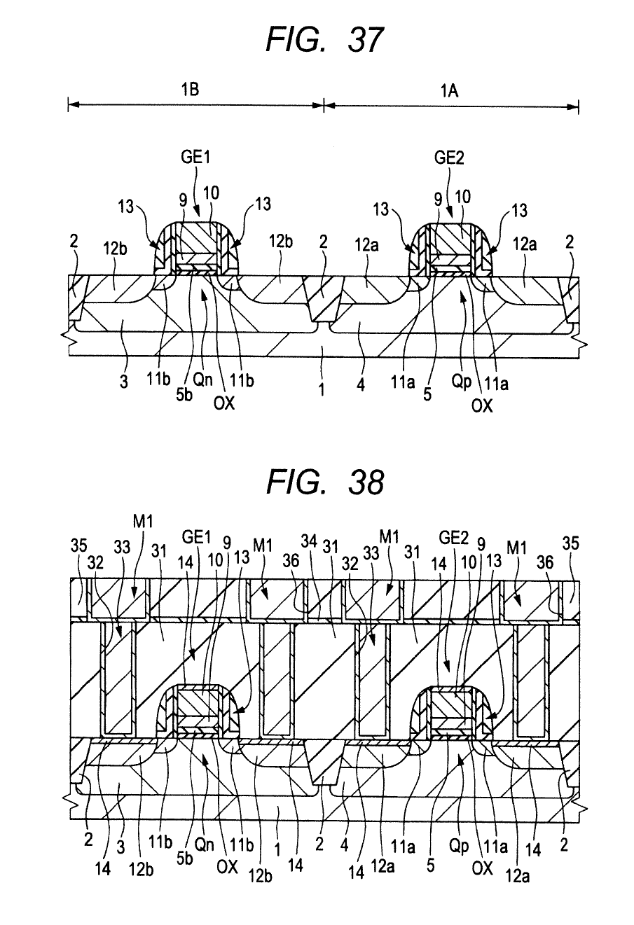

Then, as shown in FIG. 37, into regions of the p type well 3 on the opposite sides of the gate electrode GE1 and the sidewalls 13 in the nMIS formation region 1B, n⁺ type semiconductor regions 12b (source and drain) are formed. Into regions of the n type well 4 on the opposite sides of the gate electrode GE2 and the sidewalls 13 in the pMIS formation region 1A, p⁺ type semiconductor regions 12a (source and drain) are formed.

Then, an annealing treatment (activation annealing or heat treatment) at about 1000° C. is performed for activation of the introduced impurities. As a result, it is possible to activate the impurities introduced into the n⁻ type semiconductor regions 11b, the p⁻ type semiconductor regions 11a, the n⁺ type semiconductor regions 12b, the p⁺ type semiconductor regions 12a, and the like.

Thus, the structure as shown in FIG. 37 is obtained. In the nMIS formation region 1B, as a field-effect transistor, the n channel type MISFET Qn is formed. Whereas, in the pMIS formation region 1A, as a field-effect transistor, the p channel type MISFET Qp is formed.

The subsequent steps are performed in the same manner as the steps described by reference to FIGS. 16 and 17 of the first embodiment. As a result, the semiconductor device of the present embodiment shown in FIG. 38 is completed. Namely, by a known salicide technology, over respective top surfaces of the n⁺ type semiconductor regions 12b, the p⁺ type semiconductor regions 12a, and the gate electrodes GE1 and GE2, the silicide layers 14 are formed. Over the main surface of the semiconductor substrate 1, the insulation film (interlayer insulation film) 31 having plugs 33 is formed. Then, by a known single damascene method, the first-layer wire M1 is formed.

In the present embodiment, as with the first embodiment, for the threshold adjustment layer 8b shown in FIG. 32, there is used a film scarcely containing oxygen and including a rare earth element (preferably, La). This prevents the following: in the nMIS formation region 1B, oxygen is diffused from the inside of the threshold adjustment layer 8b into the Hf- and Ln-containing insulation film 5b; and the oxygen is diffused from the inside of the Hf- and Ln-containing insulation film 5b into the semiconductor substrate 1. This prevents the following: at the top surface of the semiconductor substrate 1 under the gate electrode GE1, there is formed an insulation film including a silicon oxide film with less easily controllable film thickness and density. The insulation film can prevent the increase in threshold voltage of the n channel type MISFET Qn shown in FIG. 38. Accordingly, it is possible to improve the performances of the semiconductor device. Further, by preventing the formation of the insulation film varying in film thickness, it is possible to prevent the equivalent oxide thickness of the gate insulation film of the n channel type MISFT Qn from varying. This prevents variations in value of the threshold voltage of the n channel type MISFET Qn, which can improve the reliability of the semiconductor device.

Further, the formation of the silicon oxide film OX prevents the formation of the insulation film. This can inhibit the increase in threshold voltage of the CMISFET. Further, between the silicon oxide films 13b forming the sidewalls 13 formed over the sidewalls of the gate electrode GE1 and the gate electrode GE1, the silicon nitride film 13a is interposed. This prevents the diffusion of oxygen from the inside of the silicon oxide film 13b into the Hf- and Ln-containing insulation film 5b. As a result, the oxygen in the Hf- and Ln-containing insulation film 5b is diffused into the main surface of the semiconductor substrate 1; accordingly, at the main surface of the semiconductor substrate 1, an insulation film including a silicon oxide film is prevented from being formed. This can inhibit the increase in threshold voltage of the n channel type MISFET Qn.

Further, as with the first embodiment, in the deposition step of the threshold adjustment layer 8b described by reference to FIG. 31, and the heat treatment step described by reference to FIG. 32, there is used the deposition/heat treatment apparatus 20 which is as shown in FIG. 5, and includes an inert gas atmosphere in the inside thereof. This can prevent the following: when the semiconductor wafer is transferred from the inside of the lanthanum film deposition device 27 into the annealing device 28, the semiconductor wafer is exposed to the atmosphere. In other words, without oxidizing the threshold adjustment layer 8b shown in FIG. 31, the heat treatment can be performed. This prevents the diffusion of oxygen into the Hf- and Ln-containing insulation film 5b shown in FIG. 32. As a result, it is possible to inhibit the increase in threshold voltage of the n channel type MISFET Qn.

### Third Embodiment

In the first embodiment, a description was given to the method for manufacturing a semiconductor device in which in both of the nMIS formation region and the pMIS formation region, the threshold adjustment layers were formed. In the present third embodiment, a description will be given to a method for manufacturing a semiconductor device in which in the nMIS formation region, the threshold adjustment layer is not formed, and only in the pMIS formation region, the threshold adjustment layer is formed.

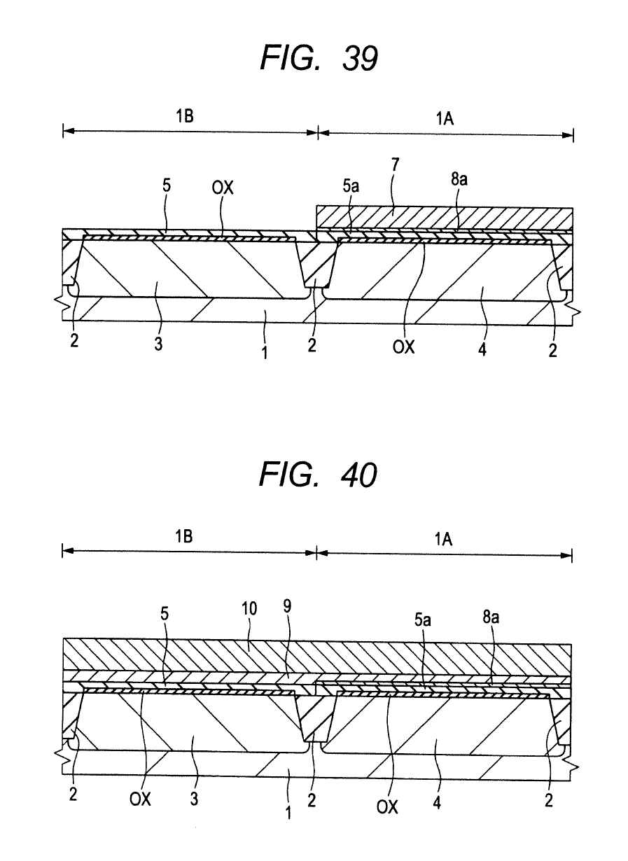

FIGS. 39 to 44 are each an essential-part cross-sectional view of the semiconductor device of the present third embodiment during a manufacturing step.

The manufacturing steps of the present embodiment are, as described by reference to FIG. 6, the same as the manufacturing steps of the first embodiment up to patterning of the threshold adjustment layer 8a and the metal nitride film 7 after the formation of the threshold adjustment layer 8a and the metal nitride film 7 over the Hf-containing insulation film 5. Therefore, herein, a description thereon is omitted, and the heat treatment step of the threshold adjustment layer 8a, and subsequent steps will be described.

After performing the same steps as the steps shown in FIGS. 1 to 6 of the first embodiment, in the present embodiment, as shown in FIG. 39, the semiconductor substrate 1 is subjected to a heat treatment. The heat treatment step can be performed at a heat treatment temperature within the range of 780 to 850° C. in an inert gas atmosphere (e.g., N₂ (nitrogen) atmosphere). By the heat treatment, in the pMIS formation region 1A, the Hf-containing insulation film 5 (see FIG. 6) and the threshold adjustment layer 8a are allowed to react with each other. Namely, by the heat treatment, the aluminum forming the threshold adjustment layer 8a is introduced (diffused) into a portion of the Hf-containing insulation film 5 in the pMIS formation region 1A.

In the heat treatment step, in the pMIS formation region 1A, the threshold adjustment layer 8a and the Hf-containing insulation film 5 are in contact with each other, and hence both are allowed to react with each other. As a result, the aluminum in the threshold adjustment layer 8a is introduced (diffused) into the Hf-containing insulation film 5.

By the heat treatment, as shown in FIG. 39, in the pMIS formation region 1A, the threshold adjustment layer 8a and the Hf-containing insulation film 5 are allowed to react (are blended or mixed) to form the Hf- and Al-containing insulation film 5a. The threshold adjustment layer 8a is not an aluminum oxide layer but a layer including aluminum. For this reason, oxygen (O) is scarcely introduced from the threshold adjustment layer 8a into the Hf-containing insulation film 5.

Then, as shown in FIG. 40, the metal nitride film 7 is removed by wet etching. Then, over the main surface of the semiconductor substrate 1, a metal film (metal layer) 9 for metal gate (metal gate electrode), and a silicon film 10 are sequentially formed. Herein, with the Hf-containing insulation film 5 in the nMIS formation region 1B exposed, the wet etching step of the metal nitride film 7 is performed. However, the Hf-containing insulation film 5 has a low resistance to the chemical for use in wet etching (e.g., APM solution or hydrofluoric acid), and hence may be damaged by wet etching.

The metal nitride film 7 is more difficult to remove by wet etching when containing oxygen than when not containing oxygen. Therefore, when the metal nitride film 7 contains oxygen in a larger amount, a longer time is taken to remove the metal nitride film 7 by wet etching. When wet etching is thus performed over a long time, the Hf-containing insulation film 5 having a low resistance to a chemical for use in wet etching suffers a larger damage.

In contrast, in the present embodiment, the threshold adjustment layer 8a shown in FIG. 39 is assumed to be a layer scarcely containing oxygen. This prevents the introduction of oxygen from the inside of the threshold adjustment layer 8a into the metal nitride film 7. Accordingly, the metal nitride film 7 can be removed in a short time with ease by wet etching. This can inhibit or prevent the etching damage inflicted on the Hf-containing insulation film 5 in the nMIS formation region 1B by the wet etching step.

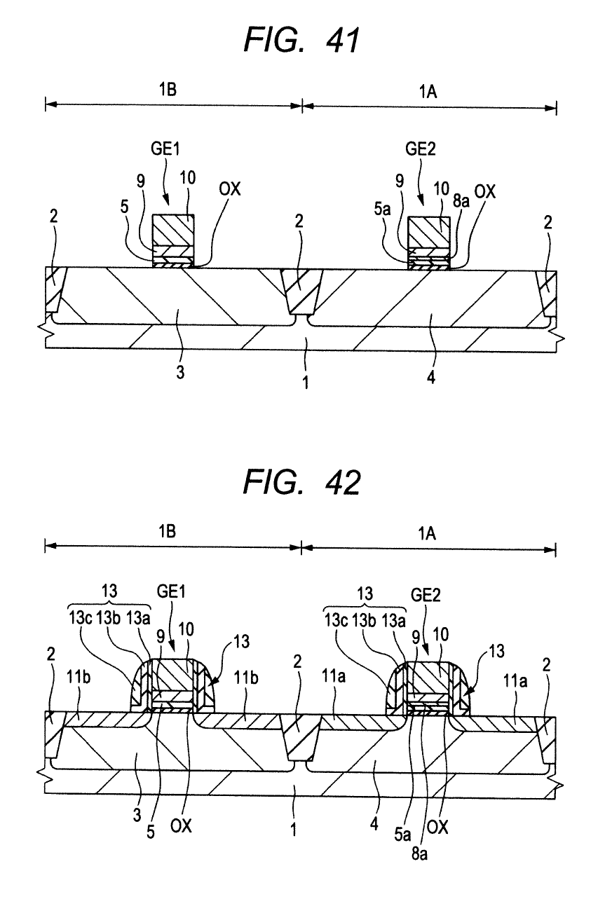

Then, as shown in FIG. 41, the lamination film of the silicon film 10 and the metal film 9 is patterned using a photolithography technology and a dry etching technology. As a result, there are formed the gate electrodes GE1 and GE2 including the metal film 9 and the silicon film 10 over the metal film 9.

The gate electrode GE1 is formed over the silicon oxide film OX via the Hf-containing insulation film 5 in the nMIS formation region 1B. The gate electrode GE2 is formed over the Hf- and Al-containing insulation film 5a in the pMIS formation region 1A.

Subsequently, as with the first embodiment, in regions of the p type well 3 on the opposite sides of the gate electrode GE1 in the nMIS formation region 1B, n⁻ type semiconductor regions (extension regions or LDD regions) 11b are formed. In regions of the n type well 4 on the opposite sides of the gate electrode GE2 in the pMIS formation region 1A, p⁻ type semiconductor regions (extension regions or LDD regions) 11a are formed.

Then, as shown in FIG. 42, over the sidewalls of the gate electrodes GE1 and GE2, sidewalls including an insulator (sidewall spacers or sidewall insulation films) 13 are formed. For example, over the semiconductor substrate 1, a silicon nitride film is formed in such a manner as to cover the gate electrodes GE1 and GE2. Then, the silicon nitride film is anisotropically etched (etched back). As a result, over respective sidewalls of the gate electrodes GE1 and GE2, the silicon nitride films 13a are left in a self-alignment manner. Subsequently, over the semiconductor substrate 1, a silicon oxide film 13b and a silicon nitride film 13c are formed sequentially from the bottom in such a manner as to cover the gate electrodes GE1 and GE2. Then, the lamination film of the silicon oxide film 13b and the silicon nitride film 13c is anisotropically etched (etched back). As a result, it is possible to form sidewalls 13 including the silicon nitride films 13a, the silicon oxide films 13b, and the silicon nitride films 13c left over the sidewalls of the gate electrodes GE1 and GE2.

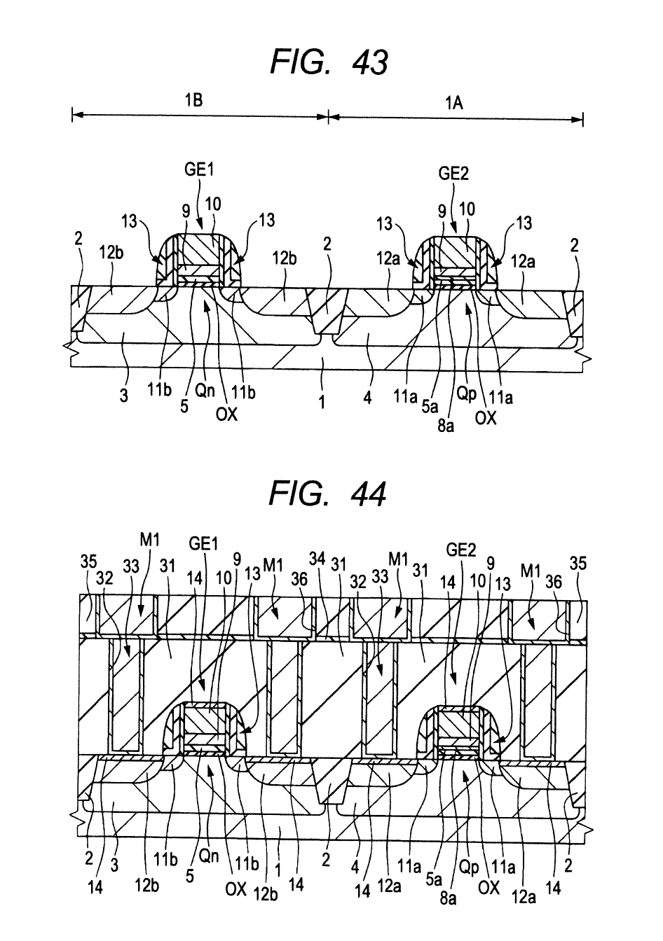

Then, as shown in FIG. 43, in regions of the p type well 3 on the opposite sides of the gate electrode GE1 and the sidewalls 13 in the nMIS formation region 1B, n⁺ type semiconductor regions 12b (source and drain) are formed. In regions of the n type well 4 on the opposite sides of the gate electrode GE2 and the sidewalls 13 in the pMIS formation region 1A, p⁺ type semiconductor regions 12a (source and drain) are formed.

Then, an annealing treatment (activation annealing or heat treatment) at about 1000° C. is performed for activation of the introduced impurities. As a result, it is possible to activate the impurities introduced into the n⁻ type semiconductor regions 11b, the p⁻ type semiconductor regions 11a, the n⁺ type semiconductor regions 12b, the p⁺ type semiconductor regions 12a, and the like.

Thus, the structure as shown in FIG. 43 is obtained. In the nMIS formation region 1B, as a field-effect transistor, the n channel type MISFET Qn is formed. Whereas, in the pMIS formation region 1A, as a field-effect transistor, the p channel type MISFET Qp is formed.

The subsequent steps are performed in the same manner as the steps described by reference to FIGS. 16 and 17 of the first embodiment. As a result, the semiconductor device of the present embodiment shown in FIG. 44 is completed. Namely, by a known salicide technology, over respective top surfaces of the n⁺ type semiconductor regions 12b, the p⁺ type semiconductor regions 12a, and the gate electrodes GE1 and GE2, the silicide layers 14 are formed. Over the main surface of the semiconductor substrate 1, the insulation film (interlayer insulation film) 31 having plugs 33 is formed. Then, by a known single damascene method, the first-layer wire M1 is formed.

In the present embodiment, as with the first embodiment, for the threshold adjustment layer 8a shown in FIG. 39, there is used a film scarcely containing oxygen and including aluminum. This prevents the following: in the pMIS formation region 1A, oxygen is diffused from the inside of the threshold adjustment layer 8a into the Hf- and Al-containing insulation film 5a; and the oxygen is diffused from the inside of the Hf- and Al-containing insulation film 5a into the semiconductor substrate 1. This prevents the following: at the top surface of the semiconductor substrate 1 under the gate electrode GE1, there is formed an insulation film including a silicon oxide film with less easily controllable film thickness and density. The insulation film can prevent the increase in threshold voltage of the p channel type MISFET Qp shown in FIG. 44. Further, by preventing the formation of the insulation film varying in film thickness, it is possible to prevent the equivalent oxide thickness of the gate insulation film of the p channel type MISFT Qp from varying.

Further, the formation of the silicon oxide film OX prevents the formation of the insulation film. This can prevent the increase in threshold voltage of the p channel type MISFET Qp. Further, between the silicon oxide films 13b forming the sidewalls 13 formed over the sidewalls of the gate electrode GE2 and the gate electrode GE2, the silicon nitride film 13a is interposed. This prevents the diffusion of oxygen from the inside of the silicon oxide film 13b into the Hf- and Al-containing insulation film 5a. As a result, the oxygen in the Hf- and Al-containing insulation film 5a is diffused into the main surface of the semiconductor substrate 1; accordingly, at the main surface of the semiconductor substrate 1, an insulation film including a silicon oxide film is prevented form being formed. This can prevent the increase in threshold voltage of the p channel type MISFET Qp.

Further, as with the first embodiment, in the step of forming the threshold adjustment layer and the metal nitride layer over the semiconductor substrate in the pMIS formation region, there is used the deposition/heat treatment apparatus 20 which includes the aluminum film deposition device 25 and the titanium nitride film deposition device 26 in an integral form as shown in FIG. 5, and includes an inert gas atmosphere in the inside thereof. Accordingly, when the semiconductor wafer is transferred from the inside of the aluminum film deposition device 25 into the titanium nitride film deposition device 26, the semiconductor wafer is prevented form being exposed to the atmosphere. Therefore, without oxidizing the threshold adjustment layer in the pMIS formation region, a metal nitride film can be formed over the threshold adjustment layer. This prevents the diffusion of oxygen into the Hf- and Al-containing insulation film 5a shown in FIG. 39. As a result, it is possible to prevent the increase in threshold voltage of the p channel type MISFET Qp.

Up to this point, the invention made by the present inventors was described based on the embodiments. However, it is naturally understood that the present invention is not limited to the embodiments, and may be variously changed within the scope not departing from the gist thereof.

The present invention is widely used for a semiconductor device having a high-k film as the gate insulation film of a CMISFET.

What is claimed is:

1. A method for manufacturing a semiconductor device,
the device having a first MISFET which is a p channel type MISFET in a first region of a semiconductor substrate, and having a second MISFET which is an n channel type MISFET in a second region of the semiconductor substrate,
the method comprising the steps of:
(a) forming, in the first region and the second region of the semiconductor substrate, a first insulation film for gate insulation films of the first and second MISFETs and containing Hf;
(b) forming an aluminum film over the first insulation film in the first region and over the first insulation film in the second region;
(c) forming a cap film over the aluminum film formed in the first region and the second region;
(d) removing the cap film and the aluminum film in the second region, and leaving the cap film and the aluminum film in the first region;
(e) after the step (d), forming a first metal film comprising a rare earth element over the first insulation film in the second region and over the cap film in the first region;
(f) performing a heat treatment, and forming the first insulation film in the first region to react with the aluminum film, and forming a second insulation film in the first region, and forming the first insulation film in the second region to react with the first metal film, and forming a third insulation film in the second region;
(g) after the step (f), removing a portion of the first metal film not reacted in the step (f);
(h) after the step (g), removing the cap film in the first region;
(i) after the step (h), forming a second metal film over the second insulation film in the first region and over the third insulation film in the second region;
(j) patterning the second metal film, and forming a first gate electrode for the first MISFET in the first region, and forming a second gate electrode for the second MISFET in the second region;
(k) introducing p type impurities into the main surface of the semiconductor substrate in regions on the opposite sides of the first gate electrode in the first region;
(l) introducing n type impurities into the main surface of the semiconductor substrate in regions on the opposite sides of the second gate electrode in the second region; and
(m) after the step (k) and the step (l), subjecting the semiconductor substrate to a heat treatment, and forming source/drain regions in the main surface of the semiconductor substrate on respective opposite sides of the first gate electrode and the second gate electrode.

2. The method for manufacturing a semiconductor device according to claim 1,
wherein the first metal film comprises a lanthanum film.

3. The method for manufacturing a semiconductor device according to claim 1,
wherein the step (b) and the step (c) are performed in an inert gas atmosphere, and
wherein after the step (b) and before performing the step (c), the semiconductor substrate is not exposed to the atmosphere.

4. The method for manufacturing a semiconductor device according to claim 1,
wherein the step (e) and the step (f) are performed in an inert gas atmosphere, and
wherein after the step (e) and before performing the step (f), the semiconductor substrate is not exposed to the atmosphere.

5. The method for manufacturing a semiconductor device according to claim 1,
wherein in the step (h), the aluminum film is not removed, and under the first gate electrode, the aluminum film is formed.

6. The method for manufacturing a semiconductor device according to claim 1,
wherein before the step (a), at the main surface of the semiconductor substrate, a fourth insulation film comprising a silicon oxide film is formed, and
wherein in the step (a), over the fourth insulation film, the first insulation film is formed.

7. The method for manufacturing a semiconductor device according to claim 1, comprising, after the step (j), and before the step (k) and the step (l), the steps of:
(j1) forming a silicon nitride film over the main surface of the semiconductor substrate in such a manner as to cover the first gate electrode and the second gate electrode;
(j2) anisotropically etching the silicon nitride film, and thereby leaving the silicon nitride film over respective sidewalls of the first gate electrode and the second gate electrode;
(j3) after the (j2), forming a fifth insulation film including a silicon oxide film over the silicon nitride film; and
(j4) anisotropically etching the fifth insulation film, and thereby forming sidewalls each including the fifth insulation film and the silicon nitride film at respective sidewalls of the first gate electrode and the second gate electrode.

8. The method for manufacturing a semiconductor device according to claim 1,
wherein after the step (e) and before performing the step (f), the semiconductor substrate is not exposed to the atmosphere, and
wherein the step (f) is performed in a gas containing oxygen.

9. The method for manufacturing a semiconductor device according to claim 1,
wherein the cap film comprises a metal nitride film.

10. A method for manufacturing a semiconductor device,
the device having a first MISFET which is a p channel type MISFET in a first region of a semiconductor substrate, and having a second MISFET which is an n channel type MISFET in a second region of the semiconductor substrate,
the method comprising the steps of:
(a) forming, in the first region and the second region of the semiconductor substrate, a first insulation film for gate insulation films of the first and second MISFETs and containing Hf;
(b) forming a cap film over the first insulation film formed in the first region and the second region;
(c) removing the cap film in the second film, and leaving the cap film in the first region;
(d) after the step (c), forming a first metal film comprising a rare earth element over the first insulation film in the second region and over the cap film in the first region;
(e) performing a heat treatment, and forming the first insulation film in the second region to react with the first metal film, and forming a third insulation film in the second region;
(f) after the step (e), removing a portion of the first metal film not reacted in the step (e);
(g) after the step (f), removing the cap film in the first region;
(h) after the step (g), forming a second metal film over the first insulation film in the first region and over the third insulation film in the second region;
(i) patterning the second metal film, and forming a first gate electrode for the first MISFET in the first region, and forming a second gate electrode for the second MISFET in the second region;
(j) introducing p type impurities into the main surface of the semiconductor substrate in regions on the opposite sides of the first gate electrode in the first region;
(k) introducing n type impurities into the main surface of the semiconductor region in regions on the opposite sides of the second gate electrode in the second region; and
(l) after the step (j) and the step (k), subjecting the semiconductor substrate to a heat treatment, and forming source/drain regions in the main surface of the semiconductor substrate in regions on respective opposite sides of the first gate electrode and the second gate electrode.

11. The method for manufacturing a semiconductor device according to claim 10, wherein the first metal film comprises a lanthanum film.

12. A method for manufacturing a semiconductor device,
the device having a first MISFET which is a p channel type MISFET in a first region of a semiconductor substrate, and having a second MISFET which is an n channel type MISFET in a second region of the semiconductor substrate,
the method comprising the steps of:
(a) forming, in the first region and the second region of the semiconductor substrate, a first insulation film for gate insulation films of the first and second MISFETs and containing Hf;
(b) forming an aluminum film over the first insulation film in the first region and over the first insulation film in the second region;
(c) forming a cap film over the aluminum film formed in the first region and the second region;
(d) removing the cap film and the aluminum film in the second region, and leaving the cap film and the aluminum film in the first region;
(e) performing a heat treatment, and forming the first insulation film in the first region to react with the aluminum film, and forming a second insulation film in the first region;
(f) after the step (e), removing the cap film in the first region;
(g) after the step (f), forming a second metal film over the first insulation film in the first region and the second region;
(h) patterning the second metal film, and forming a first gate electrode for the first MISFET in the first region, and forming a second gate electrode for the second MISFET in the second region;
(i) introducing p type impurities into the main surface of the semiconductor substrate in regions on the opposite sides of the first gate electrode in the first region;
(j) introducing n type impurities into the main surface of the semiconductor region in regions on the opposite sides of the second gate electrode in the second region; and
(k) after the step (i) and the step (j), subjecting the semiconductor substrate to a heat treatment, and forming source/drain regions in the main surface of the semiconductor substrate in regions on respective opposite sides of the first gate electrode and the second gate electrode.

13. The method for manufacturing a semiconductor device according to claim 12,
wherein the step (b) and the step (c) are performed in an inert gas atmosphere, and
wherein after the step (b), and before performing the step (c), the semiconductor substrate is not exposed to the atmosphere.

14. The method for manufacturing a semiconductor device according to claim 12,
wherein in the step (h), the aluminum film is not removed, and
wherein the aluminum film is formed under the first gate electrode.
